(19) United States
(12) Patent Application Publication
(10) Pub. No.: US 2026/0247994 A1
(43) Pub. Date: Aug. 20, 2026

(54) Power Semiconductor Device Package

(71) Applicant: Wolfspeed, Inc., Durham, NC (US)

(72) Inventor: Afshin Dadvand, Durham, NC (US)

(21) Appl. No.: 19/057,233

(22) Filed: Feb. 19, 2025

(51) Int. Cl. H01L 23/495; H01L 23/31; H01L 23/373

(52) U.S. Cl. CPC H10W 70/435; H10W 40/257; H10W 74/114

(57) ABSTRACT

A power semiconductor device package is provided. The power semiconductor device package includes a submount, a semiconductor die on a first side of the submount, one or more reinforcing structures spaced apart from the semiconductor die on the submount, and a housing (e.g., encapsulating material) formed around at least a portion of the submount. In some examples, the reinforcing structure may include a different coefficient of thermal expansion (CTE) relative to the submount and/or the housing. In some examples, the reinforcing structure may include a different modulus of elasticity relative to the submount and/or the housing.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a power semiconductor device package. The power semiconductor device package includes a submount comprising a first side and a second side opposite the first side. The power semiconductor device package further includes a semiconductor die on the first side of the submount. The power semiconductor device package further includes a reinforcing structure on the submount, the reinforcing structure spaced apart from the semiconductor die, the reinforcing structure comprising a different coefficient of thermal expansion (CTE) relative to the submount. The power semiconductor device package further includes a housing comprising an encapsulating material formed around at least a portion of the submount.

Another example aspect of the present disclosure is directed to a power semiconductor device package. The power semiconductor device package includes a submount comprising a first side and a second side opposite the first side. The power semiconductor device package further includes a semiconductor die on the first side of the submount. The power semiconductor device package further includes a first reinforcing structure on the first side of the submount. The power semiconductor device package further includes a second reinforcing structure on the second side of the submount, the second reinforcing structure being different from the first reinforcing structure. The power semiconductor device package further includes a housing comprising an encapsulating material formed around at least a portion of the submount.

Another example aspect of the present disclosure is directed to a method. The method includes providing a semiconductor die on a submount. The method further includes providing a reinforcing structure on the submount spaced apart from the semiconductor die, the reinforcing structure comprising a different coefficient of thermal expansion (CTE) relative to the submount. The method further includes providing an encapsulating material around the semiconductor die, the reinforcing structure, and the submount to form a power semiconductor device package.

Another example aspect of the present disclosure is directed to a power semiconductor device package. The power semiconductor device package includes a submount comprising a first side and a second side opposite the first side. The power semiconductor device package includes a semiconductor die on the first side of the submount. The power semiconductor device package further includes a reinforcing structure on the submount, the reinforcing structure spaced apart from the semiconductor die, the reinforcing structure comprising a greater modulus of elasticity relative to the submount. The power semiconductor device package further includes a housing comprising an encapsulating material formed around at least a portion of the submount.

Another example aspect of the present disclosure is directed to a power semiconductor device package. The power semiconductor device package includes a submount comprising a first side and a second side that is opposite the first side. The power semiconductor device package further includes a semiconductor die on the first side of the submount. The power semiconductor device package further includes a reinforcing structure on the first side of the submount, the reinforcing structure spaced apart from the semiconductor die, the reinforcing structure comprising a greater coefficient of thermal expansion (CTE) relative to the submount. The power semiconductor device package further includes a housing comprising an encapsulating material formed around at least a portion of the submount.

Another example aspect of the present disclosure is directed to a power semiconductor device package. The power semiconductor device package includes a submount comprising a first side and a second side that is opposite the first side. The power semiconductor device package further includes a semiconductor die on the first side of the submount. The power semiconductor device package further includes a reinforcing structure on the second side of the submount, the reinforcing structure comprising a lower coefficient of thermal expansion (CTE) relative to the submount. The power semiconductor device package further includes a housing comprising an encapsulating material formed around at least a portion of the submount.

Another example aspect of the present disclosure is directed to a power semiconductor device package. The power semiconductor device package includes a submount comprising a first side and a second side opposite the first side. The power semiconductor device package further includes a semiconductor die on the first side of the submount. The power semiconductor device package further includes a reinforcing structure embedded in the submount, the reinforcing structure comprising a different coefficient of thermal expansion (CTE) relative to the submount. The power semiconductor device package further includes a housing comprising an encapsulating material formed around at least a portion of the submount.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a top perspective view of an example power semiconductor device package according to example embodiments of the present disclosure;

FIG. 2 depicts a bottom perspective view of the example power semiconductor device package of FIG. 1 according to example embodiments of the present disclosure;

FIG. 3 depicts a top plan view of the example power semiconductor device package of FIG. 1 according to example embodiments of the present disclosure;

FIG. 4 depicts a bottom plan view of the example power semiconductor device package of FIG. 1 according to example embodiments of the present disclosure;

FIGS. 5A-5C depict cross-sectional views of an example submount of a power semiconductor device package according to example embodiments of the present disclosure;

FIGS. 6A-6C depict cross-sectional views of an example submount of a power semiconductor device package according to example embodiments of the present disclosure;

FIGS. 7A-7D depict bottom plan views of an example power semiconductor device package according to example embodiments of the present disclosure;

FIGS. 8A-8D depict top plan views of example power semiconductor device packages according to example embodiments of the present disclosure;

FIG. 9 depicts an example power semiconductor device package according to example embodiments of the present disclosure;

FIGS. 10A-10C depict plan views of an example power semiconductor device package according to example embodiments of the present disclosure;

FIGS. 11A-11C depict plan views of an example power semiconductor device package according to example embodiments of the present disclosure;

FIG. 12 depicts a flow chart diagram of an example method according to example embodiments of the present disclosure;

FIG. 13 depicts an example semiconductor package of a semiconductor device according to example embodiments of the present disclosure; and

FIG. 14 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages, such as power semiconductor device packages (e.g., discrete power semiconductor device packages, power modules, etc.), have been developed that include a semiconductor die (e.g., semiconductor die). In some examples, such semiconductor die include one or more semiconductor devices, such as a metal-oxide-semiconductor field-effect transistor (MOSFET), a Schottky diode, and/or a high electron mobility transistor (HEMT) device. Power semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Power semiconductor device packages with Schottky diodes and/or HEMT devices may be employed in many of the same high-performance power applications described above with respect to MOSFETs. In some examples, power semiconductor device packages with Schottky diodes may be employed in systems that also include power semiconductor device packages with MOSFETs.

Example aspects of the present disclosure are directed to power semiconductor device packages (e.g., discrete power semiconductor device packages, power modules, etc.) for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide (SiC) and/or a Group III-nitride (e.g., gallium nitride).

In some examples, the one or more semiconductor die may include one or more semiconductor devices, such as transistors, diodes, thyristors, and/or the like. It should be understood that the terms “semiconductor device(s)” and/or “power semiconductor device(s)” may be used interchangeably. For instance, in some examples, the one or more semiconductor die may include a metal-oxide-semiconductor field-effect transistor (MOSFET), such as a silicon carbide-based MOSFET. Additionally and/or alternatively, in some examples, the one or more semiconductor die may include a Schottky diode, such as a silicon carbide-based Schottky diode. In such examples, the Schottky diode(s) may be located between a first (e.g., cathode) lead and a second (e.g., anode) lead of a power semiconductor device package to form, for instance, a vertical structure power semiconductor device. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices and silicon carbide-based Schottky diode devices for purposes of illustration and discussion. Those having ordinary skill in the art, using the disclosures provided herein, will understand that the power semiconductor device packages of the present disclosure may include other power semiconductor devices without deviating from the scope of the present disclosure, such as, by way of non-limiting example, diodes (e.g., PiN diodes, etc.), insulated gate bipolar transistors, HEMTs, and/or other devices. Furthermore, it should be understood that aspects of the present disclosure are discussed with reference to vertical structure power semiconductor devices for purposes of illustration and discussion. Those having ordinary skill in the art, using the disclosures provided herein, will understand that power semiconductor device packages of the present disclosure may include other forms of power semiconductor devices without deviating from the scope of the present disclosure, such as, by way of non-limiting example, horizontal or lateral power semiconductor devices and/or the like.

In some power semiconductor device packages, the one or more semiconductor die may be attached to a submount, such as a lead frame, a power substrate (e.g., direct bonded copper (DBC) substrate, active metal brazed (AMB) substrate, etc.), and/or the like, by a die-attach material between the one or more semiconductor die and the submount. For instance, in some examples, a die-attach material may be deposited on the submount, and the semiconductor die (and/or other component) may be placed on the die-attach material. The die-attach material may be subjected to bonding and/or a bonding process (e.g., sintering) to secure the semiconductor die (and/or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s) (e.g., aluminum (Al) wire bond(s), copper (Cu) wire bond(s), copper-clad aluminum (CCA) wire bond(s), aluminum-clad copper (ACC) wire bond(s), etc.) for interconnection between portions of the one or more semiconductor die (e.g., a gate contact) and the package (e.g., lead frame). Additionally and/or alternatively, in some examples, the power semiconductor device package may use ribbon bond(s) (e.g., aluminum (Al) ribbon bond(s), copper (Cu) ribbon bond(s), copper-clad aluminum (CCA) ribbon bond(s), aluminum-clad copper (ACC) ribbon bond(s), etc.) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. More particularly, in some examples, the housing may be and/or may include an encapsulating material (e.g., epoxy mold compound (EMC), ceramic-based encapsulating material(s), silicon-based encapsulating material(s), polymer-based encapsulating material(s), etc.) formed around at least a portion of the submount and the one or more semiconductor die. The power semiconductor device package may also include one or more electrical leads extending from the housing. In some examples, the power semiconductor device package may include a plurality of electrical leads, each of which may extending from a same side of the housing relative to one another. Additionally and/or alternatively, in other examples, the power semiconductor device package may include a plurality of electrical leads, at least one of which extending from a different side of the housing relative to the other electrical leads. It should be understood that, as used herein, a “plurality of electrical leads” includes at least two, or more, electrical leads extending from the housing.

The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Packaging technology for power semiconductor devices plays an important role in defining the performance of the power semiconductor devices and of the power semiconductor device package as a whole. For example, the packaging of a power semiconductor device package may limit the ability of the one or more semiconductor die to dissipate heat, conduct current, or even switch at particular speeds (e.g., due to stray inductance). Ineffective heat dissipation can create problems for power semiconductor devices (e.g., small form factor semiconductor devices) or in situations where the power semiconductor device comes into close contact with the housing. Excessive heat can adversely impact the operation of the power semiconductor device itself, as well as the electronic system that uses that power semiconductor device.

As such, power semiconductor device packages often undergo a variety of tests during and after the manufacturing and/or fabrication process to determine the quality, reliability, and functionality of the power semiconductor device package and its various components. As one example, one such reliability test, which is known by those having ordinary skill in the art as “thermal cycling” (TC), is commonly used to stress test the microstructural reliability and durability of microelectronic devices, such as the power semiconductor devices and packages described herein. In particular, thermal cycling is a process in which power semiconductor devices and power semiconductor device packages are subjected to repeated, quick cycles of alternating extreme temperature changes to simulate real-world operating conditions. In this manner, thermal cycling may be used to identify potential reliability issues of power semiconductor device packages (and its internal components, materials, etc.), such as thermomechanical-induced failures.

However, thermal cycling tests (and/or other temperature-related reliability tests) may adversely affect the power semiconductor devices and packages due to the repeated material expansion and contraction caused by the extreme temperature changes, which may manifest as thermomechanical stress-induced failures, solder joint fatigue, degradation and delamination, metallization failures, warpage, and/or the like. Moreover, the temperature-induced anomalies and degradation may be compounded during actual use of the power semiconductor device/package under real-world operating conditions, particularly during high-temperature operation (e.g., around and/or above an upper bound of its temperature rating).

As one example, substantial warpage may occur in a power semiconductor device package (and its internal components) during and/or after the fabrication and manufacturing process. In such instances, the induced warpage may result in degraded performance, reliability, lifespan, etc. of the effected power semiconductor device package. As used herein, “warpage” refers to any surface deviation (e.g., bending, distortion, etc.) in a power semiconductor device package and/or its internal components. Warpage often occurs due to a mismatch in coefficients of thermal expansion (CTE(s)) between different components within the power semiconductor device package. For instance, a CTE mismatch between the encapsulating material (e.g., of the housing) and different parts of the semiconductor die and/or submount may induce a shear stress and/or a biaxial thermomechanical stress, thereby leading to warpage, plastic deformation and/or wrinkling, ratcheting, and/or the like.

To address the thermomechanical stress-related challenges described herein, example aspects of the present disclosure are directed to power semiconductor device packages having reinforced submounts. More particularly, a power semiconductor device package of the present disclosure may include a semiconductor die on a submount. The power semiconductor device package may further include a reinforcing structure on the submount that is spaced apart from the semiconductor die. The reinforcing structure may be provided on the submount in any suitable manner using any suitable process, such as, by way of non-limiting example, brazing, laminating, plating, sintering, and/or the like. Furthermore, the reinforcing structure may be arranged on the submount in any suitable manner, configuration, arrangement, etc. For instance, in some examples, the reinforcing structure may be on a same side of the submount relative to the semiconductor die. In some examples, the reinforcing structure may be on an opposing side of the submount relative to the semiconductor die. In some examples, a power semiconductor device package of the present disclosure may include a reinforcing structure on both sides of the submount.

As described in greater detail below, the reinforcing structure may have a different coefficient of thermal expansion (CTE) and/or modulus of elasticity relative to the submount, thereby strengthening the power semiconductor device package against and/or increasing the resistance of the power semiconductor device package to warpage. For instance, in some examples, the reinforcing structure may include a metal and/or a metal alloy, such as, by way of non-limiting example, aluminum (Al), a copper-zinc (CuZn) alloy, a nichrome alloy, an iron-chromium (FeCr) alloy, an iron-nickel (FeNi) alloy, a cobalt-chromium (CoCr) alloy, and/or the like. In some examples, the reinforcing structure may include a non-metal material, such as, by way of non-limiting example, a carbon fiber-based composite material, a ceramic-based material, and/or the like.

Aspects of the present disclosure provide a number of technical effects and benefits. For instance, power semiconductor device packages of the present disclosure may include one or more reinforcing structures on a submount that reduce an amount of warpage (and/or other thermomechanical-induced stressors) that would otherwise occur during and/or after the manufacturing process, fabrication process, packaging process, and/or the like. More particularly, by providing a reinforcing structure that has a different coefficient of thermal expansion (CTE) and/or a different modulus of elasticity relative to the submount, a bending force induced in the submount may be counteracted, thereby increasing the structural robustness and rigidity of the power semiconductor device package and its internal components. In this manner, reinforcing structures of the present disclosure may mitigate the anomalies and/or failures resulting from warpage and other thermomechanical-related stressors, thereby improving overall reliability, enhancing performance, and prolonging the lifespan of power semiconductor device packages. Thus, example aspects of the present disclosure provide robust power semiconductor devices and power semiconductor device packages with increased reliability, durability, and performance at or beyond normal operating and/or testing conditions. Furthermore, example reinforcing structures of the present disclosure may be provided on and/or arranged within the power semiconductor device package in a number of different configurations, thereby providing enhanced design flexibility during the fabrication process. In this manner, power semiconductor device packages of the present disclosure may be precisely designed (e.g., due to decreased warpage) and, as such, may be compatible with and/or suitable for a vast range of different end-use applications.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

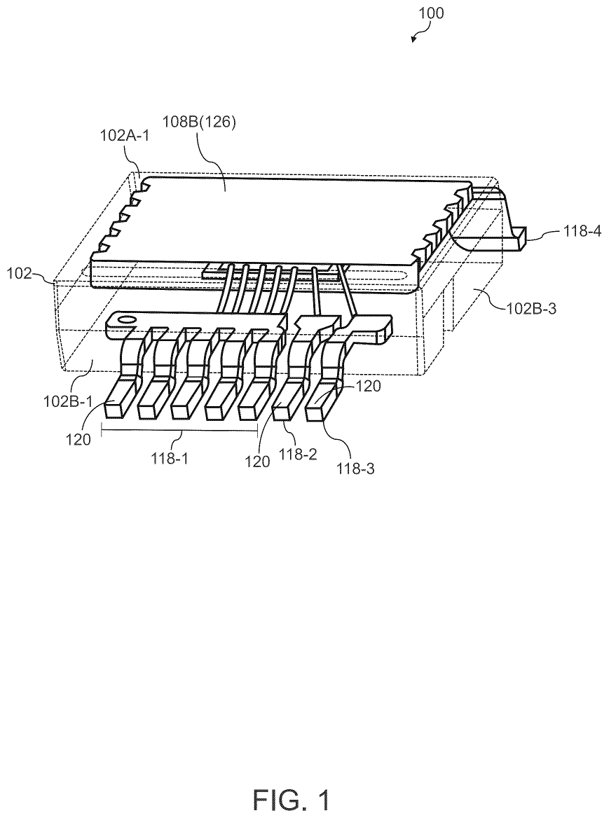

FIGS. 1-4 depict an example power semiconductor device package 100 according to example embodiments of the present disclosure. Although the power semiconductor device package 100 is depicted and described herein as a power module, those having ordinary skill in the art, using the disclosures provided herein, will understand that example aspects of the present disclosure may also be applicable to other power semiconductor device packages, such as discrete power semiconductor device packages, integrated power systems, and/or the like, without deviating from the scope of the present disclosure.

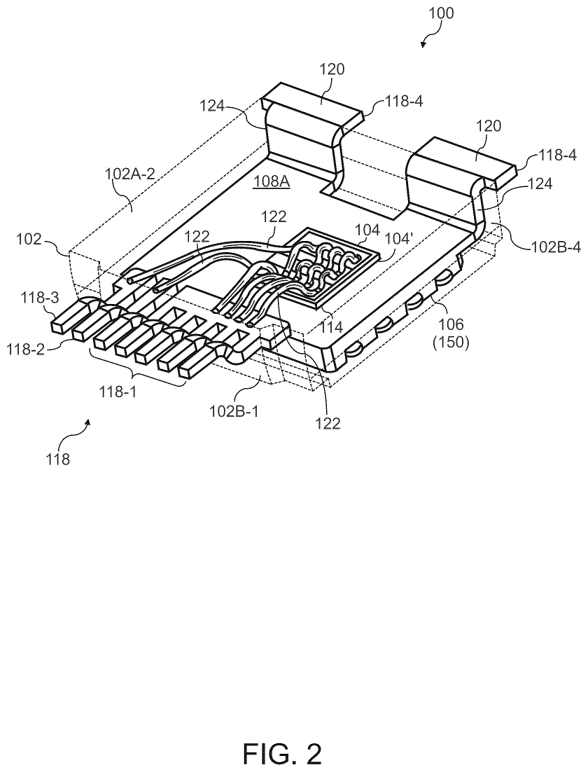

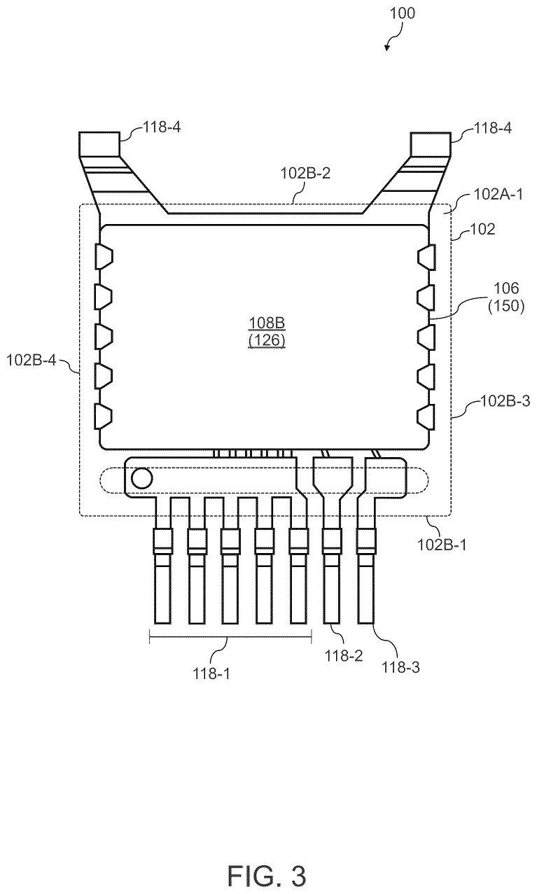

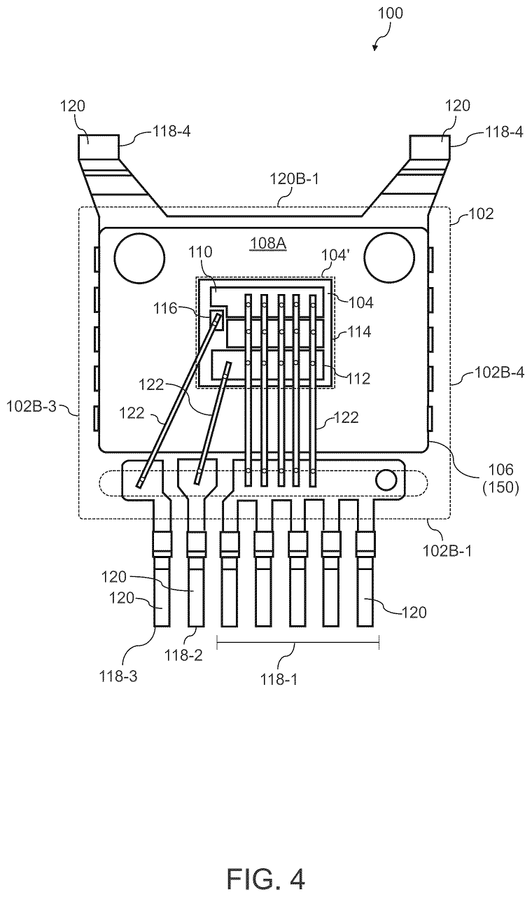

Referring now to FIGS. 1-4, FIG. 1 depicts a top perspective view of the power semiconductor device package 100, FIG. 2 depicts a bottom perspective view of the power semiconductor device package 100, FIG. 3 depicts a top plan view of the power semiconductor device package 100, and FIG. 4 depicts a bottom plan view of the power semiconductor device package 100. It should be understood that FIGS. 1-4 are intended to represent structures for purposes of identification and description and are not intended to represent structures to physical scale.

As shown, the power semiconductor device package 100 includes a housing 102. The housing 102 may be formed by a molding process, such as any suitable molding process. The housing 102 may include and/or otherwise be formed from an encapsulating material that is capable of high temperature operation, such as a temperature of about 200° C. or greater. For instance, by way of non-limiting example, the encapsulating material that forms the housing 102 may include an epoxy mold compound (EMC), a ceramic-based encapsulating material, a silicon-based encapsulating material, a polymer-based encapsulating material, and/or the like. It should be understood that the housing 102 is depicted as transparent in FIGS. 1-4 for purposes of illustration and discussion.

The housing 102 may include one or more surfaces and/or one or more sides. For instance, the housing 102 may include one or more “major” sides 102A and one or more “minor” sides 102B. As noted above, a “major side(s)” and/or a “major surface(s)” refers to a primary (e.g., most significant) surface(s) of the housing 102, such as the principal face(s) of the housing 102, the side(s) having the largest surface area, and/or the like. Conversely, a “minor side(s)” and/or a “minor surface(s)” refers to a secondary (e.g., less prominent) surface(s) of the housing 102 relative to the “major side(s),” such as the side surface(s) of the housing 102, the side(s) having a smaller surface area relative to the principal face(s), and/or the like. It should be understood that, when describing the housing 102, the terms “surface” and “side” may be used interchangeably.

In some examples, such as that depicted in FIGS. 1-4, the housing 102 may include a first major side 102A-1 (e.g., front/top side) (e.g., FIGS. 1, 3) and a second major side 102A-2 (e.g., back/bottom/rear side) (e.g., FIGS. 2, 4) (collectively, “sides 102A”). The second major side 102A-2 may be generally opposite the first major side 102A-1. The first major side 102A-1 and the second major side 102A-2 are hereinafter referred to as side 102A-1 and side 102A-2, respectively. As shown in FIGS. 1-4, the sides 102A may generally parallel relative to one another and may be the principal faces of the housing 102.

The housing 102 may further include one or more minor sides 102B adjacent to and extending between the sides 102A. More particularly, the housing 102 may further include a first minor side 102B-1 (e.g., front/bottom side surface), a second minor side 102B-2 (e.g., top/back side surface), a third minor side 102B-3 (e.g., right side surface), and a fourth minor side 102B-4 (e.g., left side surface) (collectively, “sides 102B”).

The first minor side 102B-1, the second minor side 102B-2, the third minor side 102B-3, and the fourth minor side 102B-4 are hereinafter referred to as side 102B-1, side 102B-2, side 102B-3, and side 102B-4, respectively. The side 102B-2 may be generally opposite the side 102B-1; the side 102B-4 may be generally opposite the side 102B-3. The sides 102B may be generally perpendicular to the sides 102A; the sides 102B-1, 102B-2 may be generally perpendicular to the sides 102B-3, 102B-4. The sides 102B-1, 102B-2 may be generally parallel relative to one another; the sides 102B-3, 102B-4 may be generally parallel relative to one another.

It should be understood that the housing 102 may include different arrangements of surfaces without deviating from the scope of the present disclosure. For instance, one or more notches and/or one or more recesses may be formed on any of the sides and/or surfaces of the housing 102 without deviating from the scope of the present disclosure.

In some examples, such as that depicted in FIGS. 1-4, the power semiconductor device package 100 may be arranged as a surface mount technology package. More particularly, one of the major sides 102A of the housing 102 may be positioned opposite an external surface, such as a printed circuit board (PCB) on which the power semiconductor device package 100 is mounted. For instance, in the example depicted in FIGS. 1-4, the side 102A-1 of the housing 102 may be positioned opposite an external surface (e.g., PCB) such that the side 102A-2 forms a mounting side of the power semiconductor device package 100 that is mounted to the external surface (e.g., PCB). Additionally and/or alternatively, in other examples, the side 102A-2 may be positioned opposite the external surface (e.g., PCB) such that the side 102A-1 forms the mounting side of the power semiconductor device package 100 that is mounted to the external surface (e.g., PCB).

The power semiconductor device package 100 may be arranged to house and provide external connections to one or more semiconductor die, such as semiconductor die 104. As shown, the semiconductor die 104 may be arranged within the housing 102. It should be understood that the power semiconductor device package 100 is depicted in FIGS. 1-4 as having one semiconductor die (e.g., semiconductor die 104) for purposes of illustration and discussion. Those having ordinary skill in the art, using the disclosures provided herein, will understand that example power semiconductor device packages of the present disclosure may include more than one semiconductor die without deviating from the scope of the present disclosure.

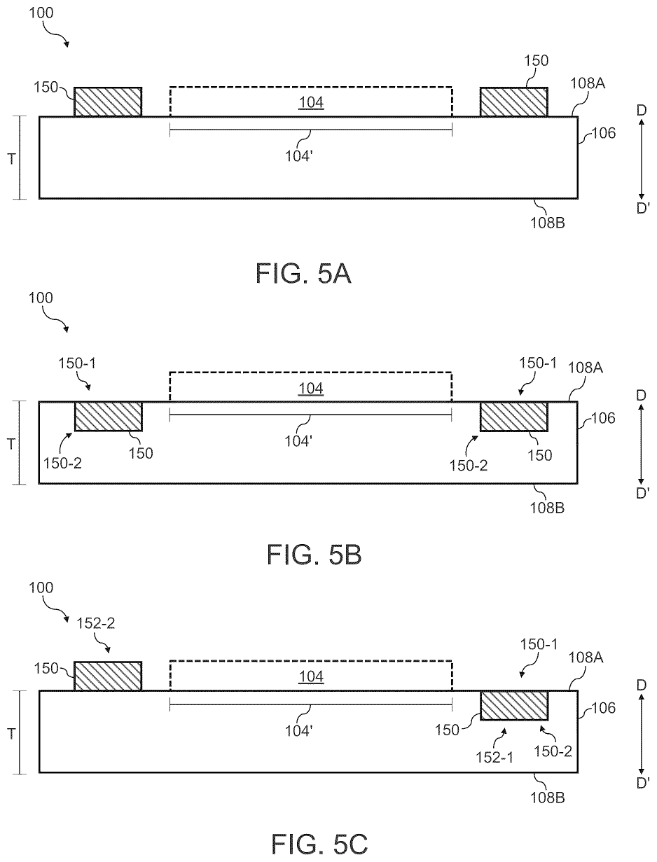

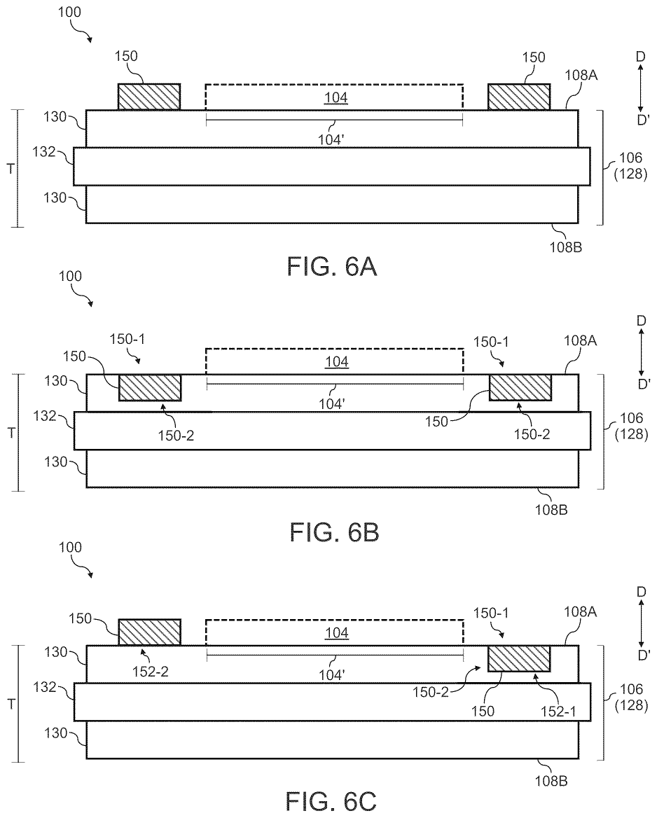

The semiconductor die 104 may be mounted on a mounting substrate, such as a submount 106. In some examples (e.g., FIGS. 5A-5C), the submount 106 may be and/or may include a lead frame, such as a conductive lead frame and/or the like. For instance, the submount 106 may include a conductive material, such as copper (Cu) and/or the like. Additionally and/or alternatively, in some examples (e.g., FIGS. 6A-6C), the submount 106 may be and/or may include a power substrate, such as a direct bonded copper (DBC) substrate, an active metal brazed (AMB) substrate, and/or the like. Additionally and/or alternatively, in some examples, the submount 106 may be and/or may include a lead frame, and the lead frame may be arranged on a power substrate.

Referring still to FIGS. 1-4, the semiconductor die 104 may be coupled to the submount 106 with, for instance, a die-attach material (not shown). In some examples, the semiconductor die 104 may be directly coupled to the submount 106. As shown, the submount 106 may include a first side 108A and a second side 108B that is opposite the first side 108A. The first side 108A and the second side 108B of the submount 106 may be the major side(s) of the submount 106. As such, for purposes of illustration and discussion, the first side 108A and the second side 108B of the submount 106 may be generally referred to herein as “side 108.” That is, as used herein, “side 108” of the submount 106 refers to one of the major side(s) of the submount 106, such as the first side 108A and/or the second side 108B.

In the example depicted in FIG. 1-4, the semiconductor die 104 is on the first side 108A of the submount 106. Hence, a surface of the semiconductor die 104 defines a die footprint 104′ on the first side 108A of the submount 106. It should be understood, however, that the semiconductor die 104 may be on the second side 108B of the submount 106 (and, hence, may define a die footprint 104′ on the second side 108B of the submount 106) without deviating from the scope of the present disclosure.

In some examples, the semiconductor die 104 may include a wide bandgap semiconductor material, such as silicon carbide (SiC), a Group III-nitride (e.g., gallium nitride (GaN)), and/or the like. The semiconductor die 104 may include one or more semiconductor devices. For instance, in some examples (e.g., FIGS. 1-4), the semiconductor die 104 may include a metal-oxide-semiconductor field-effect transistor (MOSFET), such as a silicon carbide-based MOSFET. In other examples, the semiconductor die 104 may include a Schottky diode. It should be understood that the semiconductor die 104 is depicted in FIGS. 1-4 as including one or more MOSFETs for purposes of illustration and discussion. Those having ordinary skill in the art, using the disclosures provided herein, will understand that the semiconductor die 104 may include any suitable semiconductor device without deviating from the scope of the present disclosure.

As noted above, the semiconductor die 104 depicted in FIGS. 1-4 includes one or more MOSFETs. In such examples, the semiconductor die 104 may include one or more metallization structures, such as one or more contacts, one or more bonding pads, and/or the like, on one or more sides of the semiconductor die 104. More particularly, as shown, the semiconductor die 104 may include a source contact 110, a gate contact 112, and a drain contact 114. The source contact 110 and the gate contact 112 may be on a first side of the semiconductor die 104 (e.g., facing side 102A-2), while the drain contact 114 may be on a second side of the semiconductor die 104 that is opposite the first side (e.g., facing side 102A-1). Additionally, in some examples (e.g., FIGS. 1-4), the semiconductor die 104 may include an additional contact 116 on the first side of the semiconductor die 104 (e.g., facing side 102A-2). By way of non-limiting example, the additional contact 116 may be a source-kelvin contact, a sensor contact, and/or the like.

Referring still to FIGS. 1-4, the power semiconductor device package 100 may include a plurality of electrical leads 118 extending from the housing 102. For instance, in some examples, the plurality of electrical leads 118 may extend from one or more minor sides 102B of the housing 102. More particularly, in some examples, the plurality of electrical leads 118 may extend from a perpendicular side of the housing 102 relative to the major sides 102A (e.g., sides 102B). Each of the plurality of electrical leads 118 may be at least partially encapsulated by the housing 102 such that a portion of each of the plurality of electrical leads 118 is exposed through a side 102B. For instance, as shown in the example depicted in FIGS. 1-4, each of the plurality of electrical leads 118 may extend from one of sides 102B-1 and/or 102B-2. It should be understood that, although depicted in FIGS. 1-4 as extending from sides 102B-1 and/or 102B-2, the plurality of electrical leads 118 may extend from any side 102A and/or side 102B without deviating from the scope of the present disclosure.

Furthermore, the plurality of electrical leads 118 may be any suitable form of electrical connection pin and/or connection structure, such as, by way of non-limiting example, extended lead(s), surface mount type (SMT) connection structure(s), Gull-wing pin(s), wettable flank connection structure(s), electrical connection pin(s), and/or the like. For instance, as shown in the example depicted in FIGS. 1-4, the plurality of electrical leads 18 may be and/or may include SMT connection structures that each include a respective connection surface 120. The connection surface 120 of each of the plurality of electrical leads 118 may be used to connect internal components of the power semiconductor device package 100 to external electrical connections.

At least one electrical lead of the plurality of electrical leads 118 may be coupled to one or more contacts (e.g., source contact 110, gate contact 112, drain contact 114, additional contact 116, etc.) of the semiconductor die 104. For instance, in the example of the semiconductor die 104 including a MOSFET, the plurality of electrical leads 118 may include one or more first leads 118-1, one or more second leads 118-2, one or more third leads 118-3, and one or more fourth leads 118-4. It should be understood that a power semiconductor device package of the present disclosure may include any number of electrical leads 118 without deviating from the scope of the present disclosure.

More particularly, as shown in FIGS. 1-4, the plurality of electrical leads 118 may include a plurality of first leads 118-1 (hereinafter “first leads 118-1”). In the example depicted in FIGS. 1-4, each of the first leads 118-1 is an integral electrical connection pin. As shown, the first leads 118-1 may be connected to the source contact 110 of the semiconductor die 104. In some examples, each of the first leads 118-1 may be connected to the source contact 110 using, for instance, one or more wire bonds 122. In this way, the first leads 118-1 may be used to connect the source of the semiconductor die 104 to one or more external connections.

The plurality of electrical leads 118 may further include a second lead 118-2. In the example depicted in FIGS. 1-4, the second lead 118-2 is an integral electrical connection pin. As shown, the second lead 118-2 may be connected to the gate contact 112 of the semiconductor die 104. In some examples, the second lead 118-2 may be connected to the gate contact 112 using, for instance, one or more wire bonds 122. In this way, the second lead 118-2 may be used to connect the gate of the semiconductor die 104 to one or more external connections.

The plurality of electrical leads 118 may further include a third lead 118-3. In the example depicted in FIGS. 1-4, the second lead 118-2 is an integral electrical connection pin. As shown, the third lead 118-3 may be connected to the additional contact 116 of the semiconductor die 104, such as a source-kelvin contact, a sensor contact, and/or the like. In some examples, the third lead 118-3 may be connected to the additional contact 116 using, for instance, one or more wire bonds 122. In this way, the third lead 118-3 may be used to connect the additional contact 116 of the semiconductor die 104 to one or more external connections.

The plurality of electrical leads 118 may further include a plurality of fourth leads 118-4 (hereinafter “fourth leads 118-4”). In the example depicted in FIGS. 1-4, each of the fourth leads 118-4 is an SMT connection structure (e.g., SMT connection tab). In some examples, each fourth lead 118-4 (e.g., each SMT connection structure) may include a connection elbow 124 that may be integral with the corresponding connection surface 120. Furthermore, at least a portion of each connection elbow 124 may be exposed through the housing 102 (e.g., the housing 102 does not encapsulate at least a portion of each connection elbow 124). In some examples, each of the fourth leads 118-4 may extend from the side 102B-2 at a location between side 102A-1 and side 102A-2. More particularly, as shown in FIGS. 1-4, each fourth lead 118-4 may extend from the side 102B-2 of the housing 102 in a direction towards side 102A-2. In some examples, at least a portion of each fourth lead 118-4 (e.g., at least a portion of each corresponding connection surface 120) may be co-planar with the side 102A-2 of the housing 102. Furthermore, as shown, the fourth leads 118-4 may be connected to the drain contact 114 of the semiconductor die 104. More particularly, the drain contact 114 of the semiconductor die 104 may be electrically coupled (e.g., via a die-attach material (not shown)) to the submount 106, and the fourth leads 118-4 may be electrically coupled to the submount 106 (e.g., via the corresponding connection elbow 124). In this way, the fourth leads 118-4 may be used to connect the drain of the semiconductor die 104 to one or more external connections.

As noted above, in some examples, the power semiconductor device package 100 may include a semiconductor die 104 with other types of semiconductor devices (e.g., bipolar junction transistor(s) (BJT(s)), insulated-gate bipolar transistor(s) (IGBT(s)), gate turn-off transistor(s) (GTO(s)), junction field-effect transistor(s) (JFET(s)), high electron mobility transistor(s) (HEMT(s)), Schottky diode(s), PiN diode(s), etc.) without deviating from the scope of the present disclosure. In examples where the semiconductor die 104 includes another type of semiconductor device, those having ordinary skill in the art, using the disclosures provided herein, will understand that plurality of electrical leads 118 may be connected and/or otherwise coupled to the semiconductor die 104 in a similar manner as described above.

For instance, as one non-limiting illustrative example, the semiconductor die 104 may include a Schottky diode. In such examples, one or more of the plurality of electrical leads 118 (e.g., any of the first leads 118-1, second lead 118-2, and/or third lead 118-3) may be coupled to a first contact of the Schottky diode on the semiconductor die 104 using, for instance, wire bonds (e.g., similar to wire bonds 122). Likewise, one or more of the plurality of electrical leads 118 (e.g., any of the fourth leads 118-4) may be coupled to a second contact of the Schottky diode, for instance, through the mounting substrate (e.g., through connection elbow 124 and submount 106).

It should be understood that the arrangement of the plurality of electrical leads 118 in FIGS. 1-4 is for purposes of illustration and discussion. Those having ordinary skill in the art, using the disclosures provided herein, will understand that the plurality of electrical leads 118 may be rearranged, adjusted, etc. without deviating from the scope of the present disclosure. It should also be noted that the power semiconductor device package 100 is depicted in FIGS. 1-4 as having nine electrical leads 118 (e.g., five first leads 118-1, one second lead 118-2, one third lead 118-3, two fourth leads 118-4) for purposes of illustration and discussion. Those having ordinary skill in the art, using the disclosures provided herein, will understand that the plurality of electrical leads 118 may have any number of electrical leads 118 having any suitable form without deviating from the scope of the present disclosure.

Referring still to FIGS. 1-4, in some examples, the power semiconductor device package 100 may further include a conductive structure, such as thermal pad 126, on a major side (e.g., side 102A-1) of the housing 102. In some examples, the thermal pad 126 may be at least partially exposed through a major side 102A (e.g., side 102A-1) of the housing 102. Additionally and/or alternatively, in some examples, the thermal pad 126 may be electrically isolated from the plurality of electrical leads 118. Additionally and/or alternatively, in some examples, the thermal pad 126 may be coupled to the drain contact 114 of the semiconductor die 104. The thermal pad 126 may include a thermally conductive material, such as a metal, and may be coupled to an external heat sink (e.g., with an electrical isolator) to provide for cooling of the power semiconductor device package 100 through the major side 102A (e.g., side 102A-1) of the housing 102. In this way, the thermal pad 126 may be operable to provide a heat dissipation path for the semiconductor die 104 through the major side 102A (e.g., side 102A-1) of the housing 102.

In some examples, the thermal pad 126 may also be electrically isolated from the semiconductor die 104 disposed within the housing 102. For instance, as described above, the semiconductor die 104, which is disposed within the housing 102, may be mounted on the submount 106 (e.g., mounting substrate) of the power semiconductor device package 100. The submount 106 may be coupled to, and/or integral with, the thermal pad 126. More particularly, as described in greater detail below (e.g., FIGS. 6A-6C), the submount 106 may be and/or may form part of a power substrate 128 (FIGS. 6A-6C), which includes a plurality of metal layers 130 and an insulating layer 132 between the metal layers 130. In such examples, the thermal pad 126 may be mounted on the insulating layer 132 of the power substrate 128 (FIGS. 6A-6C). In this manner, the thermal pad 126 may, in such examples, be electrically isolated from the semiconductor die 104. In some examples (e.g., FIGS. 1-4), the thermal pad 126 may be and/or may form part of a lead frame (e.g., submount 106).

As noted above, the power semiconductor device package 100 may undergo a series of reliability tests (e.g., thermal cycling) during and/or after the manufacturing and/or fabrication process. However, such reliability tests may adversely affect the power semiconductor device package 100 (and its internal components) by causing a number of different anomalies, failures, etc. in the power semiconductor device package 100 and its internal components. For instance, thermal cycling tests (and/or other temperature-related reliability test) may cause substantial warpage in the semiconductor die 104, the submount 106, etc.

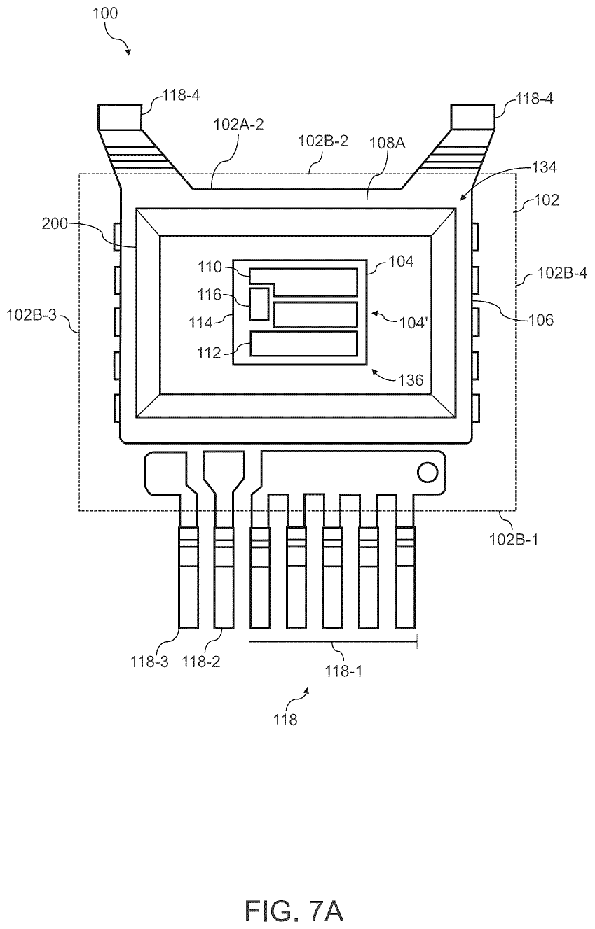

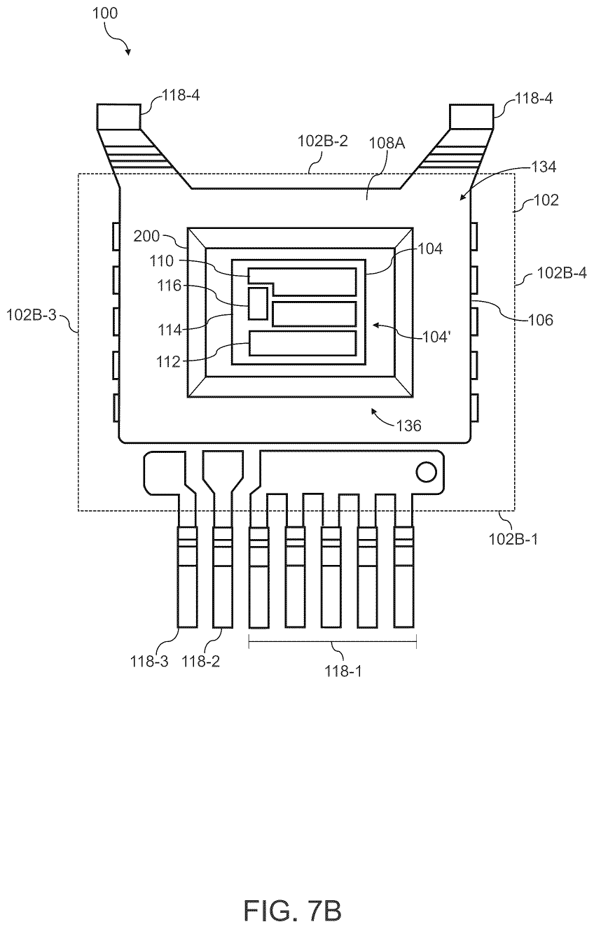

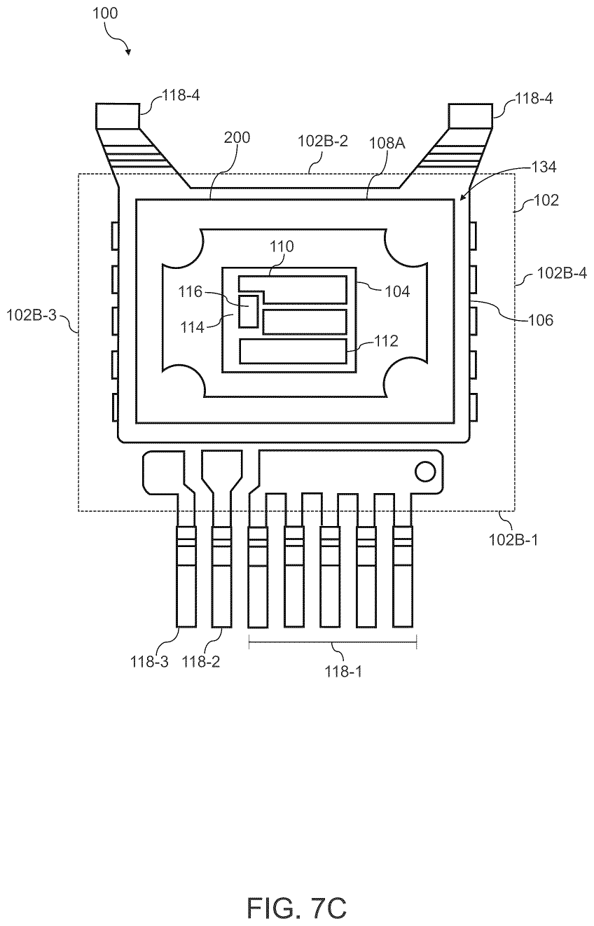

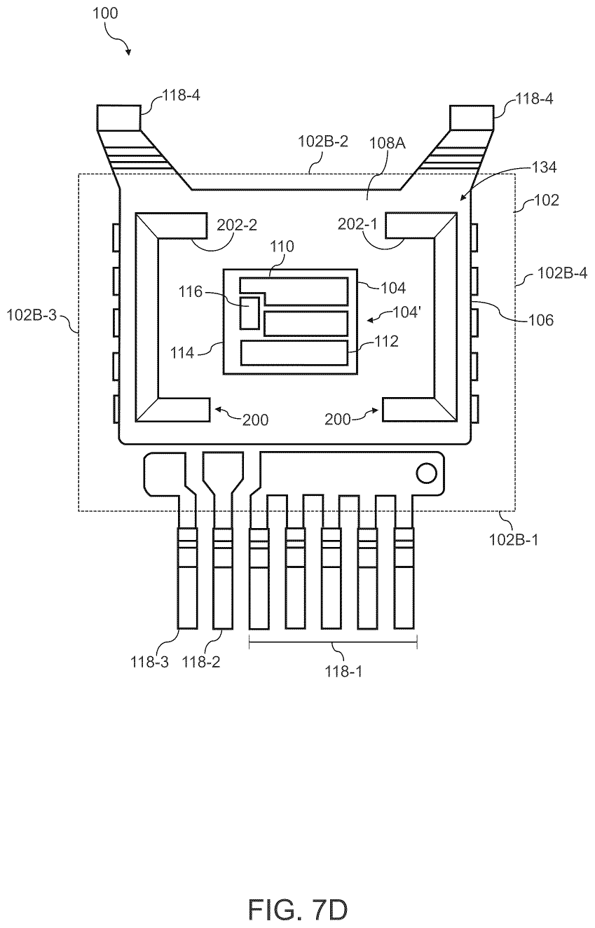

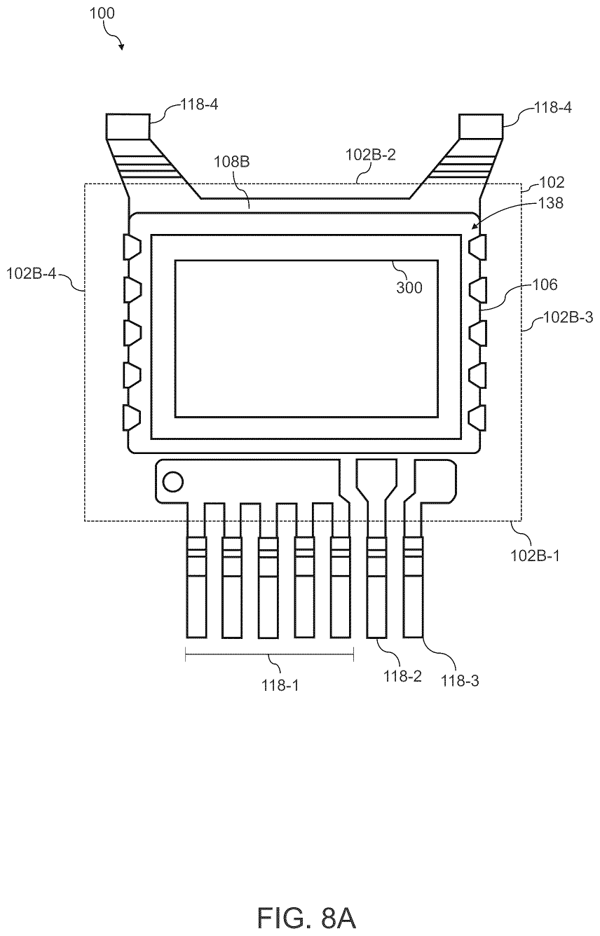

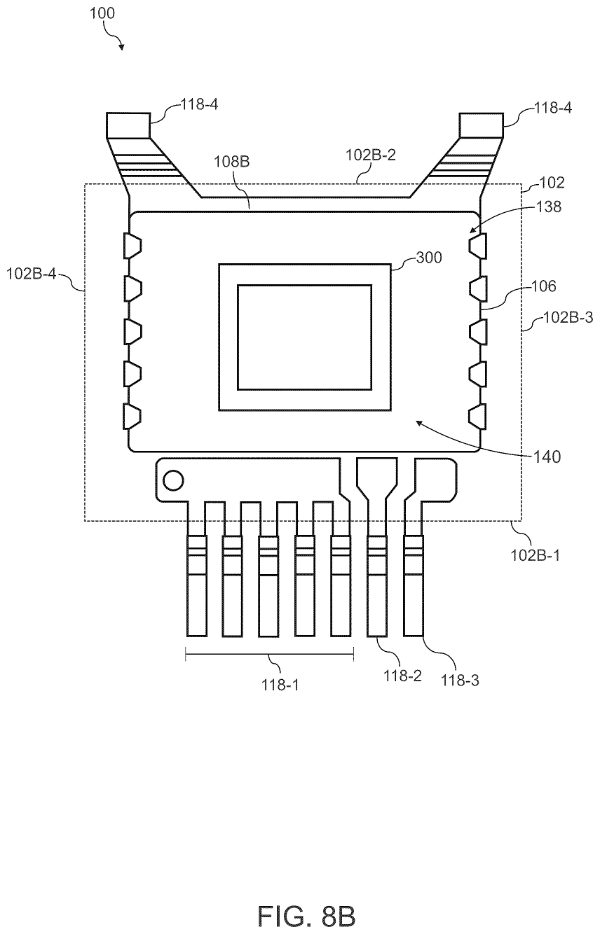

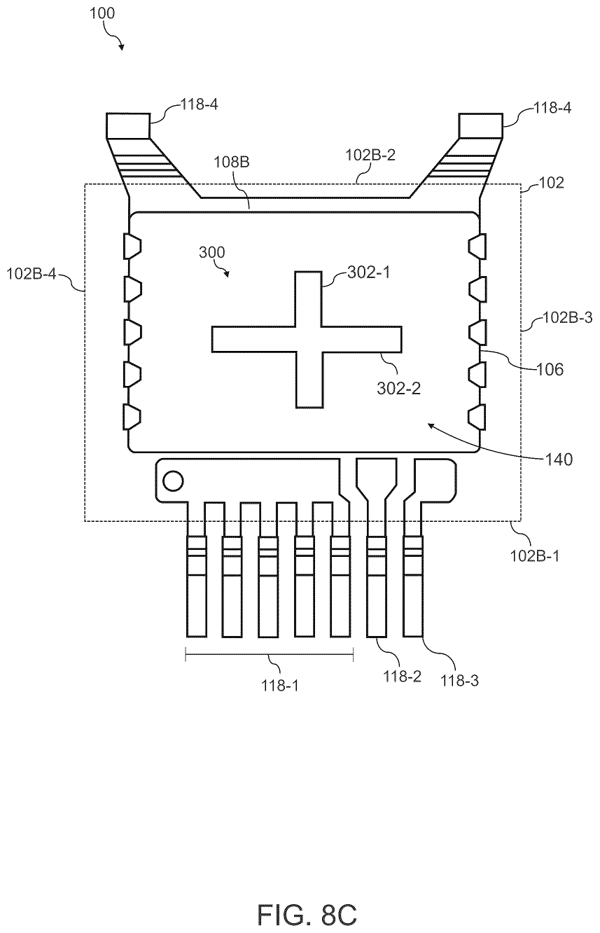

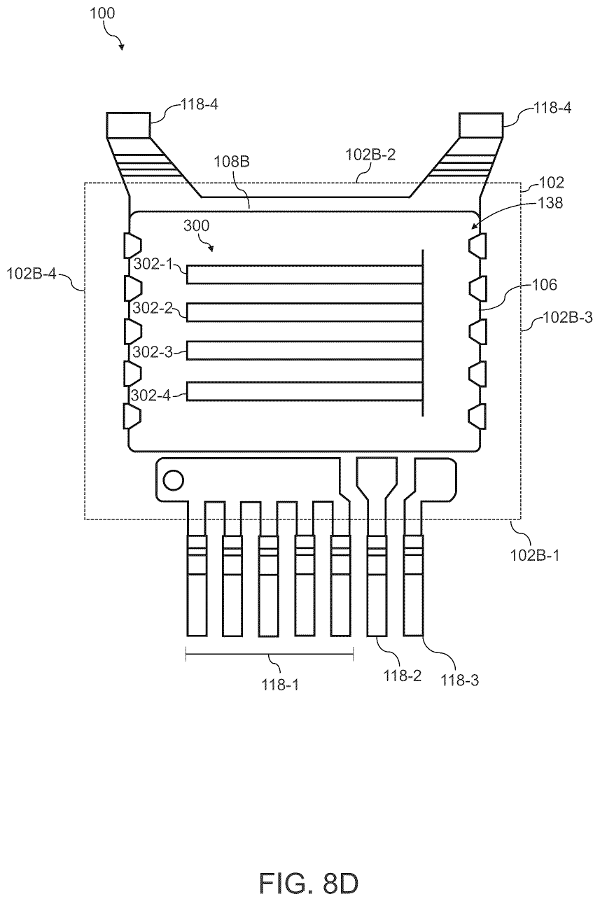

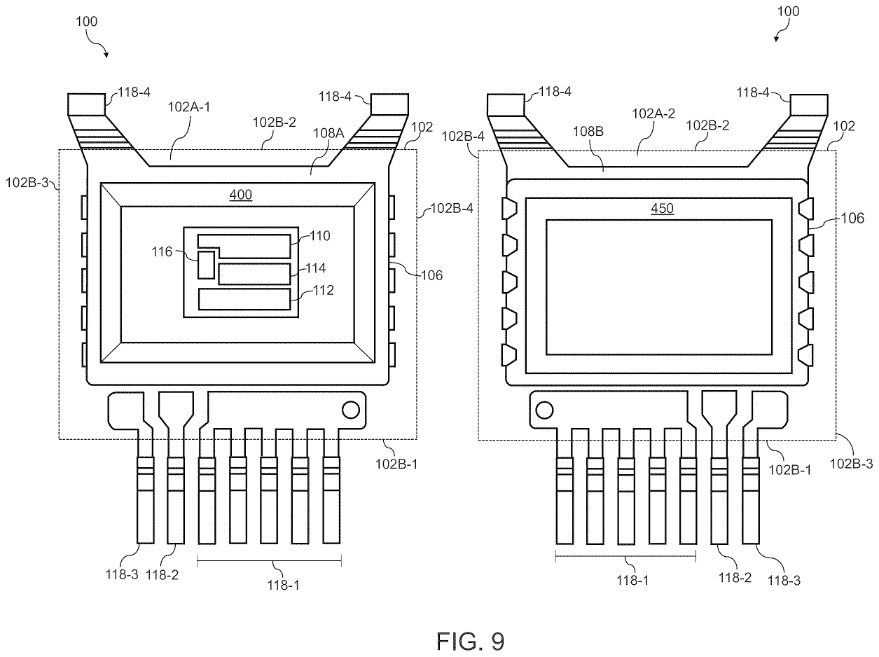

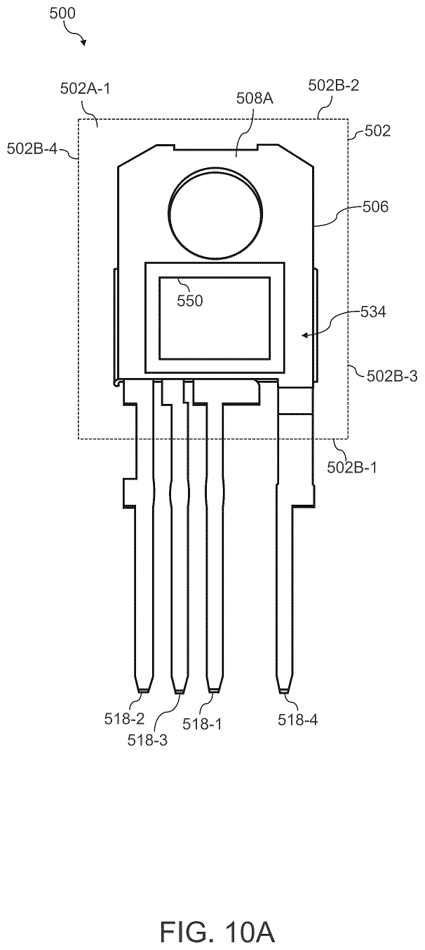

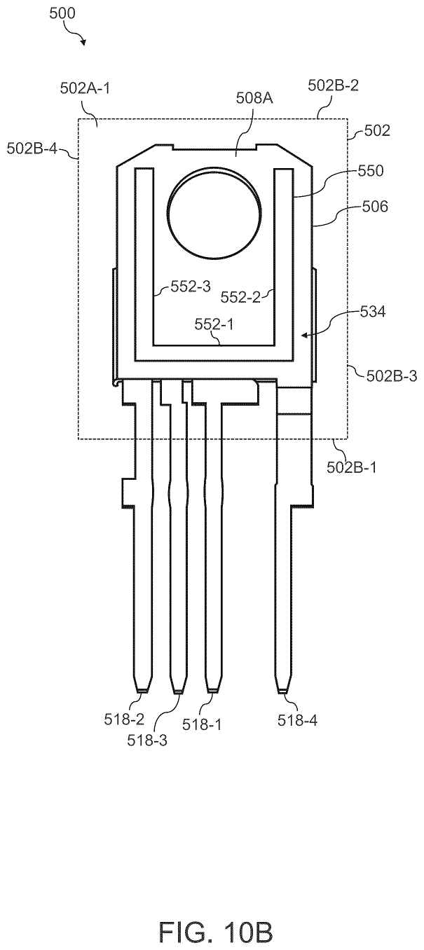

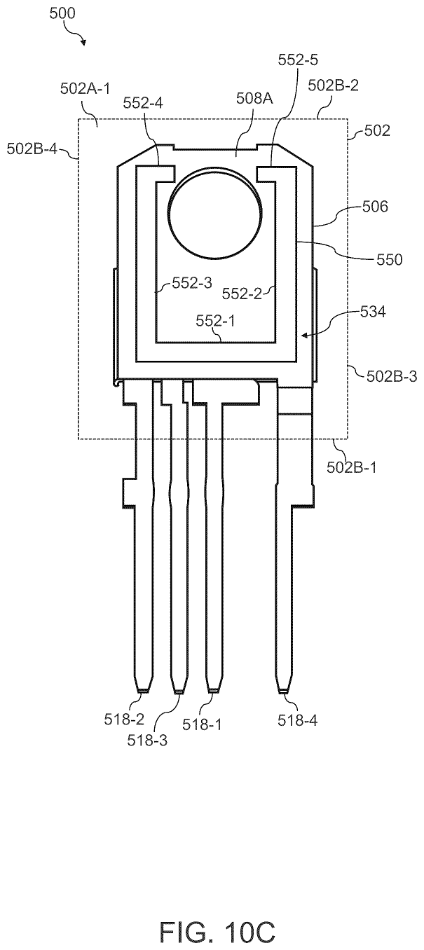

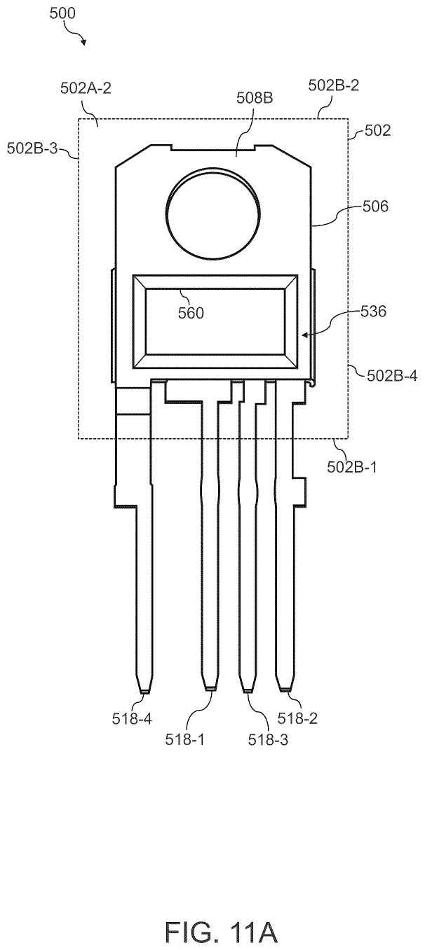

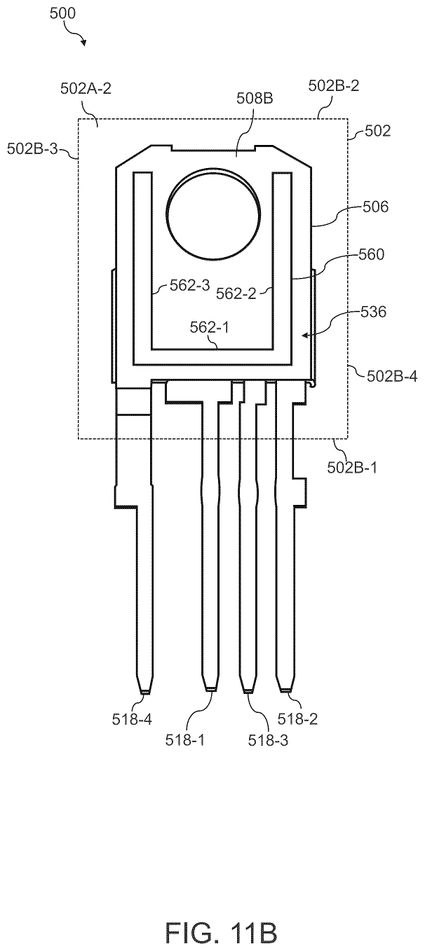

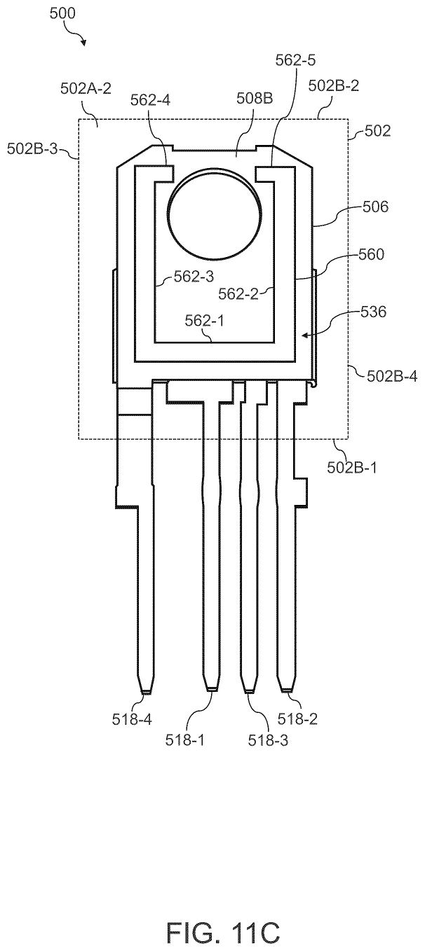

To address the aforementioned concerns, the power semiconductor device package 100 may further include a reinforcing structure 150 (example reinforcing structure(s) are discussed in greater detail with reference to FIGS. 7A-7D, 8A-8D, 9, 10A-10C, 11A-11C) that is spaced apart from the semiconductor die 104 on the submount 106. The reinforcing structure 150 may be, and/or may be similar to, any of the reinforcing structure(s) described herein (e.g., reinforcing structure 200 (FIGS. 7A-7D), reinforcing structure 300 (FIGS. 8A-8D), reinforcing structures 400 and 450 (FIG. 9), reinforcing structure 550 (FIGS. 10A-10C), reinforcing structure 560 (FIGS. 11A-11C), etc.). The reinforcing structure 150 may be configured such that the structural robustness, rigidity, and/or the like, of the power semiconductor device package 100 is increased, thereby reducing an amount of warpage (and/or other thermomechanical-induced stressors) that would otherwise occur during and/or after the manufacturing, fabrication, packaging, and operation of the power semiconductor device package 100. That is, to counteract the bending force induced in the submount 106, the reinforcing structure 150 may have a different coefficient of thermal expansion (CTE) relative to the submount 106. In some examples, the reinforcing structure 150 may likewise have a different CTE relative to the encapsulating material that forms the housing 102. Additionally, the reinforcing structure 150 may also have a greater modulus of elasticity relative to the submount 106. For instance, in some examples, the reinforcing structure 150 may have a modulus of elasticity that is at least 1.5 times greater, such as at least 2 times greater, than a modulus of elasticity of the submount 106. Furthermore, the reinforcing structure 150 may have a thickness in a range of about 0.05 millimeters to about 2 millimeters, such as a thickness in a range of about 0.1 millimeters to about 1 millimeter, such as a thickness of about 0.5 millimeters.

For instance, in some examples, the reinforcing structure 150 may include a metal and/or a metal alloy such as, by way of non-limiting example, aluminum (Al) and/or an aluminum-based alloy, a copper-zinc (CuZn) alloy, a nichrome alloy, an iron-chromium (FeCr) alloy, an iron-nickel (FeNi) alloy, a cobalt-chromium (CoCr) alloy, and/or the like. Additionally and/or alternatively, in some examples, the reinforcing structure 150 may include a non-metal material such as, by way of non-limiting example, a carbon fiber-based composite material, a ceramic-based material, and/or the like.

The reinforcing structure 150 may be provided on the submount in any suitable manner. By way of non-limiting example, the reinforcing structure 150 may be brazed on the submount 106, laminated on the submount 106, plated on the submount 106, sintered on the submount 106, and/or the like. Those having ordinary skill in the art, using the disclosures provided herein, will understand that the reinforcing structure 150 may be provided on the submount 106 in any suitable manner without deviating from the scope of the present disclosure.

In some examples (e.g., FIGS. 7A-7D), the reinforcing structure 150 may be on the first side 108A of the submount 106. Additionally and/or alternatively, in some examples (e.g., FIGS. 8A-8D), the reinforcing structure 150 may be on the second side 108B of the submount 106. Additionally and/or alternatively, in some examples (e.g., FIG. 9), the power semiconductor device package 100 may include more than one reinforcing structure 150 such that at least one reinforcing structure 150 is on the first side 108A of the submount 106 and at least one reinforcing structure 150 is on the second side 108B of the submount 106. Furthermore, in examples where the submount 106 is not a lead frame, the reinforcing structure 150 may not be directly coupled to any of terminals of the power semiconductor device package 100, such as any of the plurality of electrical leads 118 because, in such examples, the terminals (e.g., plurality of electrical leads 118) do not form part of the submount 106.

The reinforcing structure 150 may be arranged on, and/or embedded in, the submount 106. As a non-limiting illustrative example, FIGS. 5A-5C depict cross-sectional views of the submount 106 according to example embodiments of the present disclosure. It should be understood that FIGS. 5A-5C are intended to represent structures for purposes of illustration and discussion and are not intended to represent the structures to physical scale.

As noted above, in some examples (e.g., FIGS. 5A-5C), the submount 106 may be and/or may include a lead frame. In such examples, the reinforcing structure 150 may be on, and/or embedded in, a major side 108 (e.g., side 108A, side 108B) of the submount 106 (e.g., lead frame). For instance, FIG. 5A depicts an illustrative example of the reinforcing structure 150 on the first side 108A of the submount 106, FIG. 5B depicts an illustrative example of the reinforcing structure 150 embedded in the first side 108A of the submount 106, and FIG. 5C depicts an illustrative example of a first portion 152-1 of the reinforcing structure 150 being embedded in the first side 108A of the submount 106 and a second portion 152-2 of the reinforcing structure 150 being on the submount 106. It should be understood that, although depicted as being on and/or embedded in the first side 108A of the submount 106, those having ordinary skill in the art, using the disclosures provided herein, will understand that the reinforcing structure 150 (and/or portions thereof) may be on and/or embedded in the second side 108B of the submount 106 without deviating from the scope of the present disclosure.

More particularly, as shown in FIG. 5A, the reinforcing structure 150 may, in some examples, be on the first side 108A of the submount 106. In such examples, the reinforcing structure 150 may extend in a perpendicular direction D away from the submount 106. That is, the reinforcing structure 150 may extend in the perpendicular direction D away from the first side 108A of the submount 106. Although not depicted in FIG. 5A, the reinforcing structure 150 may also be on the second side 108B of the housing 102. In such examples, the reinforcing structure 150 may extend in a perpendicular direction D′ away from the submount 106. That is, in examples where the reinforcing structure 150 is on the second side 108B of the submount 106, the reinforcing structure 150 may extend in the perpendicular direction D′ away from the second side 108B of the submount 106.

Additionally and/or alternatively, referring now to FIG. 5B, the reinforcing structure 150 may, in some examples, be embedded in the first side 108A of the submount 106. In such examples, the reinforcing structure 150 may extend from the first side 108A of the submount 106 in the perpendicular direction D′ into a thickness T of the submount 106. That is, the reinforcing structure 150 may be embedded in the first side 108A of the submount 106 such that at least a first portion 150-1 of the reinforcing structure 150 is co-planar with the first side 108A of the submount 106, and at least a second portion 150-2 of the reinforcing structure 150 may be embedded within the thickness T of the submount 106 (e.g., at least the second portion 150-2 may extend in the perpendicular direction D′ away from the first side 108A towards the second side 108B). Although not depicted in FIG. 5B, the reinforcing structure 150 may also be embedded within the second side 108B of the submount 106. In such examples, the reinforcing structure 150 may extend from the second side 108B of the submount 106 in the perpendicular direction D into the thickness T of the submount 106. That is, the reinforcing structure 150 may be embedded in the second side 108B of the submount 106 such that at least the first portion 150-1 of the reinforcing structure 150 is co-planar with the second side 108B of the submount 106, and at least the second portion 150-2 of the reinforcing structure 150 may be embedded within the thickness T of the submount 106 (e.g., at least the second portion 150-2 may extend in the perpendicular direction D away from the second side 108B towards the first side 108A).

Additionally and/or alternatively, referring now to FIG. 5C, the reinforcing structure 150 may, in some examples, be both on the first side 108A of the submount 106 and also embedded in the first side 108A of the submount 106. As described herein, in some examples, the reinforcing structure 150 may include a first portion 152-1 and a second portion 152-2 that is different from the first portion 152-1. In some examples, the first portion 152-1 of the reinforcing structure 150 may be embedded in the first side 108A of the submount 106 in a similar manner as described above with reference to FIG. 5B, while the second portion 152-2 of reinforcing structure 150 may be on the first side 108A of the submount 106 in a similar manner as described above with reference to FIG. 5A. Although not depicted in FIG. 5C, the reinforcing structure 150 may also be both on the second side 108B of the submount 106 and also embedded in the second side 108B of the submount 106. In such examples, the first portion 152-1 of the reinforcing structure 150 may be embedded in the second side 108B of the submount 106 in a similar manner as described above with reference to FIG. 5B, and the second portion 152-2 may be on the second side 108B of the submount 106 in a similar manner as described above with reference to FIG. 5A.

It should be understood that the cross-sectional profile of the reinforcing structure 150 depicted in FIGS. 5A-5C is for purposes of illustration and discussion and is not intended to be limiting. Those having ordinary skill in the art, using the disclosures provided herein, will understand that the reinforcing structure 150 may have any suitable cross-sectional profile without deviating from the scope of the present disclosure.

As another non-limiting illustrative example, FIGS. 6A-6C depict cross-sectional views of the submount 106 according to example embodiments of the present disclosure. It should be understood that FIGS. 6A-6C are intended to represent structures for purposes of illustration and discussion and are not intended to represent the structures to physical scale.

As noted above, in some examples (e.g., FIGS. 6A-6C), the submount 106 may be and/or may include a power substrate, such as power substrate 128 (e.g., direct bonded copper (DBC) substrate, an active metal brazed (AMB) substrate, etc.). Referring generally to FIGS. 6A-6C, as shown, the power substrate 128 may include a plurality of metal layers 130 and an insulating layer 132 between the metal layers 130. The insulating layer 132 may be formed from an insulating material, such as, by way of non-limiting example, a ceramic material and/or other insulating material(s). For purposes of illustration and discussion, the metal layer 130 that corresponds to the first side 108A of the submount 106 (e.g., power substrate 128) is referred to as metal layer 130A, and the opposing metal layer 130 (e.g., on the opposing side of the insulating layer 132) that corresponds to the second side 108B of the submount 106 (e.g., power substrate 128) is referred to as metal layer 130B.

As described herein (and as depicted above in FIGS. 5A-5C), the reinforcing structure 150 may be on, and/or embedded in, a major side 108 (e.g., side 108A, side 108B) of the submount 106. In examples in which the submount 106 is and/or otherwise includes the power substrate 128 (FIGS. 6A-6C), the reinforcing structure 150 may be on, and/or embedded in, one of the metal layers 130 (e.g., metal layer 130A, metal layer 130B) of the power substrate 128. For instance, FIG. 6A depicts an illustrative example of the reinforcing structure 150 on the first side 108A (e.g., metal layer 130A) of the power substrate 128, FIG. 6B depicts an illustrative example of the reinforcing structure 150 embedded in the first side 108A (e.g., metal layer 130A) of the power substrate 128, and FIG. 6C depicts an illustrative example of the first portion 152-1 of the reinforcing structure 150 being embedded in the first side 108A (e.g., metal layer 130A) of the power substrate 128 and the second portion 152-2 of the reinforcing structure 150 being on the first side 108A (e.g., metal layer 130A) of the power substrate 128. It should be understood that, although depicted as being on and/or embedded in the metal layer 130A of the power substrate 128, those having ordinary skill in the art, using the disclosures provided herein, will understand that the reinforcing structure 150 (and/or portions thereof) may be on and/or embedded in the metal layer 130B of the power substrate 128 without deviating from the scope of the present disclosure.

More particularly, as shown in FIG. 6A, the reinforcing structure 150 may, in some examples, be on the first side 108A of the power substrate 128. In such examples, the reinforcing structure 150 may extend in the perpendicular direction D away from the first side 108A of the power substrate 128 in a similar manner as described above with reference to FIG. 5A. That is, the reinforcing structure 150 may extend in the perpendicular direction D away from the metal layer 130A of the power substrate 128. Although not depicted in FIG. 6A, the reinforcing structure 150 may also be on the second side 108B of the power substrate 128. In such examples, the reinforcing structure 150 may extend in the perpendicular direction D′ away from the second side 108B of the power substrate 128. That is, in examples where the reinforcing structure 150 is on the second side 108B of the power substrate 128, the reinforcing structure 150 may extend in the perpendicular direction D′ away from the metal layer 130B of the power substrate 128.

Additionally and/or alternatively, referring now to FIG. 6B, the reinforcing structure 150 may, in some example, be embedded in the first side 108A of the power substrate 128. In such examples, the reinforcing structure 150 may extend from the first side 108A of the power substrate 128 in the perpendicular direction D′ into a thickness T of the power substrate 128 in a similar manner as described above with reference to FIG. 5B. That is, the reinforcing structure 150 may be embedded in the metal layer 130A of the power substrate 128 such that at least a first portion 150-1 of the reinforcing structure 150 is co-planar with the first side 108A of the power substrate 128, and at least a second portion 150-2 of the reinforcing structure 150 may be embedded within the thickness T of the power substrate 128 (e.g., at least the second portion 150-2 may extend in the perpendicular direction D′ away from the first side 108A towards the insulating layer 132 and metal layer 130B). Although not depicted in FIG. 6B, the reinforcing structure 150 may also be embedded within the second side 108B of the power substrate 128. In such examples, the reinforcing structure 150 may extend from the second side 108B of the power substrate 128 in the perpendicular direction D into the thickness T of the power substrate 128. That is, the reinforcing structure 150 may be embedded in the metal layer 130B of the power substrate 128 such that at least the first portion 150-1 of the reinforcing structure 150 is co-planar with the second side 108B of the power substrate 128, and at least a second portion 150-2 of the reinforcing structure 150 may be embedded within the thickness T of the power substrate 128 (e.g., at least the second portion 150-2 may extend in the perpendicular direction D away from the second side 108B towards the insulating layer 132 and metal layer 130A).

Additionally and/or alternatively, referring now to FIG. 6C, the reinforcing structure 150 may, in some examples, be both on the first side 108A of the power substrate 128 and also embedded in the first side 108A of the power substrate 128 in a similar manner as described above with reference to FIG. 5C. As noted above, in some examples, the reinforcing structure 150 may include the first portion 152-1 and the second portion 152-2 that is different from the first portion 152-1. In some examples, the first portion 152-1 of the reinforcing structure 150 may be embedded in the first side 108A of the power substrate 128 (e.g., in the metal layer 130A) in a similar manner as described above with reference to FIG. 6B, while the second portion 152-2 of the reinforcing structure 150 may be on the first side 108A of the power substrate 128 (e.g., on the metal layer 130A) in a similar manner as described above with reference to FIG. 6A. Although not depicted in FIG. 6C, the reinforcing structure 150 may also be both on the second side 108B of the power substrate 128 (e.g., on the metal layer 130B) and also embedded in the second side 108B of the power substrate 128 (e.g., embedded in the metal layer 130B). In such examples, the first portion 152-1 of the reinforcing structure 150 may be embedded in the second side 108B of the power substrate 128 (e.g., in the metal layer 130B) in a similar manner as described above with reference to FIG. 6B, while the second portion 152-2 of the reinforcing structure 150 may be on the second side 108B of the power substrate 128 (e.g., on the metal layer 130B) in a similar manner as described above with reference to FIG. 6A.

It should be understood that the cross-sectional profile of the reinforcing structure 150 depicted in FIGS. 6A-6C is for purposes of illustration and discussion and is not intended to be limiting. Those having ordinary skill in the art, using the disclosures provided herein, will understand that the reinforcing structure 150 may have any suitable cross-sectional profile without deviating from the scope of the present disclosure.

Variations and modifications may be made to the example power semiconductor device package 100 described herein without deviating from the scope of the present disclosure, such as a size, shape, configuration, arrangement, etc. of the reinforcing structure (e.g., reinforcing structure 150, etc.) in the power semiconductor device package 100. As non-limiting illustrative examples, FIGS. 7A-7D depict bottom plan views of the power semiconductor device package 100 according to example embodiments of the present disclosure. More particularly, FIGS. 7A-7D depict the power semiconductor device package 100 with example configurations of a reinforcing structure 200 on, and/or embedded in, the first side 108A of the submount 106. The reinforcing structure 200 may be similar to any of the reinforcing structures described herein, such as the reinforcing structure 150 (e.g., FIGS. 1-6C) and/or the like. It should be understood that FIGS. 7A-7D are intended to represent structures for purposes of illustration and discussion and are not intended to represent the structures to physical scale.

Referring to FIGS. 7A-7D, as noted above, the reinforcing structure 200 may be on the first side 108A of the submount 106 and/or may be embedded in the first side 108A of the submount 106. In such examples, the reinforcing structure 200 may have a greater CTE relative to the submount 106. The reinforcing structure 200 may also have a different CTE relative to the encapsulating material that forms the housing 102. The reinforcing structure 200 may further have a greater modulus of elasticity relative to the submount 106, such as a modulus of elasticity that is at least 1.5 times greater, such as at least 2 times greater, than a modulus of elasticity of the submount 106. It should be understood that the housing 102 is depicted as transparent in FIGS. 7A-7D for purposes of illustration and discussion.

As shown (FIGS. 7A-7D), the reinforcing structure 200 may be arranged outside of the die footprint 104′ on the first side 108A of the submount 106. In some examples (FIG. 7A-7C), the reinforcing structure 200 may have a closed shape that extends around the semiconductor die 104 (e.g., outside of the die footprint 104′). More particularly, in some examples (FIGS. 7A-7B), the reinforcing structure 200 may have a rectangular shape. Additionally and/or alternatively, in other examples (FIG. 7C), the reinforcing structure 200 may have a non-rectangular shape. In some examples (FIGS. 7A, 7C), the reinforcing structure 200 may extend to a periphery 134 of the first side 108A of the submount 106. In some examples (FIG. 7B), the reinforcing structure 200 may extend around a periphery 136 of die footprint 104′.

In some examples (FIG. 7D), the reinforcing structure 200 may have an open shape. More particularly, the reinforcing structure 200 may include a plurality of portions 202 that are different relative to one another. For instance, in some examples (FIG. 7D), the reinforcing structure 200 may include a first portion 202-1 that is spaced apart from an opposing second portion 202-2. Those having ordinary skill in the art, using the disclosures provided herein, will understand that the example reinforcing structure 200 may have any number of portions 202 without deviating from the scope of the present disclosure.

Additionally and/or alternatively, in some examples (FIG. 7D), the reinforcing structure 200 may include a plurality of metal strips 204 on the first side 108A of the submount 106. Put differently, in the example depicted in FIG. 7D, the first portion 202-1 may be a first metal strip 204-1, and the second portion 202-2 may be a second metal strip 204-2. As shown in FIG. 7D, the first metal strip 204-1 (e.g., first portion 202-1) and the second metal strip 204-2 (e.g., second portion 202-2) are outside of the die footprint 104′ on opposite sides of the semiconductor die 104 relative to one another. Those having ordinary skill in the art, using the disclosures provided herein, will understand that an example reinforcing structure of the present disclosure may have any number of metal strips 204 without deviating from the scope of the present disclosure.

FIGS. 7A-7D depict example reinforcing structures 200 for purposes of illustration and discussion. Those of ordinary skill in the art, using the disclosures provided herein, will understand that different reinforcing structure configurations may be used without deviating from the scope of the present disclosure.

Additional variations and modifications may be made to the example power semiconductor device package 100 described herein without deviating from the scope of the present disclosure, such as a size, shape, configuration, arrangement, etc. of the reinforcing structure (e.g., reinforcing structure 150, reinforcing structure 200, etc.) in the power semiconductor device package 100. As non-limiting illustrative examples, FIGS. 8A-8D depict top plan views of the power semiconductor device package 100 according to example embodiments of the present disclosure. More particularly, FIGS. 8A-8D depict the power semiconductor device package 100 with example configurations of a reinforcing structure 300 on, and/or embedded in, the second side 108B of the submount 106. The reinforcing structure 300 may be similar to any of the reinforcing structures described herein, such as the reinforcing structure 150 (e.g., FIGS. 1-6C), the reinforcing structure 200 (e.g., FIGS. 7A-7D), and/or the like. It should be understood that FIGS. 8A-8D are intended to represent structures for purposes of illustration and discussion and are not intended to represent the structures to physical scale.

Referring to FIGS. 8A-8D, as noted above, the reinforcing structure 300 may be on the second side 108B of the submount 106 and/or may be embedded in the second side 108B of the submount 106. In such examples, the reinforcing structure 300 may have a lower CTE relative to the submount 106. The reinforcing structure 300 may also have a different CTE relative to the encapsulating material that forms the housing 102. The reinforcing structure 300 may further have a greater modulus of elasticity relative to the submount 106, such as a modulus of elasticity that is at least 1.5 times greater, such as at least 2 times greater, than a modulus of elasticity of the submount 106. It should be understood that the housing 102 is depicted as transparent in FIGS. 8A-8D for purposes of illustration and discussion.

As shown (FIGS. 8A-8D), the reinforcing structure 300 may have a closed shape. In some examples (FIG. 8A), the reinforcing structure 300 may have a closed, rectangular shape that extends around a periphery 138 of the second side 108B of the submount 106. Additionally and/or alternatively, in some examples (FIG. 8B), the reinforcing structure 300 may have a closed, rectangular shape that extends around a central portion 140 of the second side 108B of the submount 106. Although not depicted, it should be understood that the reinforcing structure 300 may also have a closed, non-rectangular shape without deviating from the scope of the present disclosure.

In some examples (FIGS. 8C-8D), the reinforcing structure 300 may have an open shape, such as any suitable rectangular and/or non-rectangular open shape. More particularly, the reinforcing structure 300 may include a plurality of portions 302 that are different relative to one another. For instance, in some examples (FIG. 8C), the reinforcing structure 300 may include a first portion 302-1 that is generally perpendicular with a second portion 302-2. In some examples (FIG. 8C), the first portion 302-1 may intersect with the second portion 302-2 on the second side 108B of the submount 106. Additionally and/or alternatively, in some examples (FIG. 8D), the reinforcing structure 300 may include a first portion 302-1, a second portion 302-2, a third portion 302-3, and a fourth portion 302-4 (collectively, portions 302). In some examples (FIG. 8D), the portions 302 may be spaced apart from one another on the second side 108B of the submount 106. In some examples (FIG. 8D), the portions 302 may be generally parallel relative to one another on the second side 108B of the submount 106. Those having ordinary skill in the art, using the disclosures provided herein, will understand that the example reinforcing structure 300 may have any number of portions 302 without deviating from the scope of the present disclosure.

In some examples (FIG. 8C), the reinforcing structure 300 may include a plurality of metal strips 304 on the second side 104B of the submount 106. Put differently, in the examples depicted in FIGS. 8C-8D, the portion 302 may be metal strips 304. In some examples (FIG. 8C), at least two of the plurality of metal strips 304 (e.g., first portion 302-1, second portion 302-2) may be generally perpendicular relative to one another. In some examples (FIG. 8C), at least two of the plurality of metal strips 304 (e.g., first portion 302-1, second portion 302-2) may intersect with one another on the second side 108B of the submount 106. In some examples (FIG. 8D), the plurality of metal strips 304 (e.g., first portion 302-1, second portion 302-2, third portion 302-3, fourth portion 302-4) may be generally parallel relative to one another on the second side 108B of the submount 106. In some examples (FIG. 8D), each of the plurality of metal strips 304 (e.g., first portion 302-1, second portion 302-2, third portion 302-3, fourth portion 302-4) may be spaced apart from one another on the second side 108B of the submount 106. Those having ordinary skill in the art, using the disclosures provided herein, will understand that an example reinforcing structure of the present disclosure may have any number of metal strips 304 without deviating from the scope of the present disclosure.

FIGS. 8A-8D depict example reinforcing structures 300 for purposes of illustration and discussion. Those of ordinary skill in the art, using the disclosures provided herein, will understand that different reinforcing structure configurations may be used without deviating from the scope of the present disclosure.

Additional variations and modifications may be made to the example power semiconductor device package 100 described herein without deviating from the scope of the present disclosure, such as a size, shape, configuration, arrangement, etc. of the reinforcing structure (e.g., reinforcing structure 150, reinforcing structure 200, reinforcing structure 300, etc.) in the power semiconductor device package 100. As non-limiting illustrative examples, FIG. 9 depicts a top plan view and a bottom plan view of the power semiconductor device package 100 according to example embodiments of the present disclosure. More particularly, FIG. 9 depicts the power semiconductor device package 100 with example configurations of a first reinforcing structure 400 on (and/or embedded in) the first side 108A of the submount 106 and a second reinforcing structure 450 on (and/or embedded in) the second side 108B of the submount 106. The first reinforcing structure 400 and the second reinforcing structure 450 may be similar to any of the reinforcing structures described herein, such as the reinforcing structure 150 (e.g., FIGS. 1-6C), the reinforcing structure 200 (e.g., FIGS. 7A-7D), the reinforcing structure 300 (FIGS. 8A-8D), and/or the like. It should be understood that FIG. 9 is intended to represent structures for purposes of illustration and discussion and are not intended to represent the structures to physical scale.

Referring to FIG. 9, as noted above, the power semiconductor device package 100 may include more than one reinforcing structure, such as the first reinforcing structure 400 (e.g., on the first side 108A of the submount 106) and the second reinforcing structure 450 (e.g., on the second side 108B of the submount 106). In such examples (FIG. 9), the first reinforcing structure 400 may have a greater CTE relative to the submount 106, and the second reinforcing structure 450 may have a lower CTE relative to the submount 106. Both the first reinforcing structure 400 and the second reinforcing structure 450 may have a different CTE relative to the encapsulating material that forms the housing 102. The reinforcing structures 400, 450 may further have a greater modulus of elasticity relative to the submount 106, such as a modulus of elasticity that is at least 1.5 times greater, such as at least 2 times greater, than a modulus of elasticity of the submount 106. It should be understood that the housing 102 is depicted as transparent in FIG. 9 for purposes of illustration and discussion.

The first reinforcing structure 400 may be similar to any of the reinforcing structures described herein, such as, by way of non-limiting example, the reinforcing structure 200 (FIGS. 7A-7D). For instance, as shown in FIG. 9, the first reinforcing structure 400 may be arranged outside of the die footprint 104′ on the first side 108A of the submount 106. The first reinforcing structure 400 may also have any suitable shape and/or configuration, such as, by way of non-limiting example, any of the shapes and/or configurations of the reinforcing structure 200 described above (FIGS. 7A-7D). For instance, the first reinforcing structure 400 may have a closed shape (e.g., FIGS. 7A-7C, 9), an open shape (e.g., FIG. 7D), a rectangular shape (e.g., FIGS. 7A-7B, 9), a non-rectangular shape (e.g., FIG. 7C), and/or the like. The first reinforcing structure 400 may further include a plurality of metal strips (not shown) (e.g., FIG. 7D) having any suitable arrangement and/or configuration on the first side 108A of the submount 106.

The second reinforcing structure 450 may be similar to any of the reinforcing structures described herein, such as, by way of non-limiting example, the reinforcing structure 300 (FIGS. 8A-8D). For instance, as shown in FIG. 9, the second reinforcing structure 450 may extend around the periphery 138 of the second side 108B of the submount 106. The second reinforcing structure 450 may also have any suitable shape and/or configuration, such as, by way of non-limiting example, any of the shapes and/or configurations of the reinforcing structure 300 described above (FIGS. 8A-8D). For instance, the second reinforcing structure 450 may have a closed shape (e.g., FIGS. 8A-8B), an open shape (e.g., FIGS. 8C-8D), a rectangular shape (e.g., FIGS. 8A-8B), a non-rectangular shape (e.g., FIG. 8C), and/or the like. The second reinforcing structure 450 may further include a plurality of metal strips (not shown) (e.g., FIGS. 8C-8D) having any suitable arrangement and/or configuration on the second side 108B of the submount 106.

FIGS. 1-9 depict an example power semiconductor device package 100 for purposes of illustration and discussion. Those of ordinary skill in the art, using the disclosures provided herein, will understand that example aspects of the present disclosure may be used in any suitable power semiconductor device package without deviating from the scope of the present disclosure.

Additional variations and modifications may be made to example power semiconductor device packages described herein without deviating from the scope of the present disclosure. As a non-limiting illustrative example, FIGS. 10A-11C depict an example power semiconductor device package 500 according to example embodiments of the present disclosure. More particularly, FIGS. 10A-10C depict top plan views of the power semiconductor device package 500, and FIGS. 11A-11C depict bottom plan views of the power semiconductor device package 500. The power semiconductor device package 500 may be similar to, and may include similar internal components as, the power semiconductor device package 100 described above with reference to FIGS. 1-9. It should be understood that FIGS. 10A-11C are intended to represent structures for purposes of illustration and discussion and are not intended to represent the structures to physical scale.

As noted above, the power semiconductor device package 500 may be similar to the power semiconductor device package 100 described above with reference to FIGS. 1-9. For instance, the power semiconductor device package 500 may include a housing 502. The housing 502 may be similar to the housing 102 described above (e.g., FIGS. 1-9). Furthermore, like the power semiconductor device package 100 (FIGS. 1-9), the power semiconductor device package 500 may be arranged to house and provide external connections to one or more semiconductor die, such as the semiconductor die 104 described above. It should be understood that the housing 502 is depicted as transparent in FIGS. 10A-11C for purposes of illustration and discussion.

In contrast to the power semiconductor device package 100, however, the semiconductor die 104 of the power semiconductor device package 500 may be arranged on submount 506 (e.g., lead frame). The power semiconductor device package 500 may further include a plurality of electrical leads 518 extending from a same side (e.g., minor side) of the housing 502. The plurality of electrical leads 518 may have the form of electrical connection pins, such as extended leads. At least one electrical lead of the plurality of electrical leads 518 may be coupled to one or more contacts (e.g., source contact 110, gate contact 112, drain contact 114, additional contact 116, etc.) of the semiconductor die 104 in a similar manner as described above with reference to the plurality of electrical leads 118 (FIGS. 1-9).

For instance, in the example of the semiconductor die 104 including a MOSFET, the plurality of electrical leads 518 may include a first lead 518-1, a second lead 518-2, a third lead 518-3, and a fourth lead 518-4.

It should be understood that the arrangement of the plurality of electrical leads 518 is for purposes of illustration and discussion. Those having ordinary skill in the art, using the disclosures provided herein, will understand that the plurality of electrical leads 518 may be rearranged, adjusted, etc. without deviating from the scope of the present disclosure. It should also be noted that the power semiconductor device package 500 is depicted as having four electrical leads 518 (e.g., one first lead 518-1, one second lead 518-2, one third lead 518-3, one fourth lead 518-4) for purposes of illustration and discussion. Those having ordinary skill in the art, using the disclosures provided herein, will understand that the power semiconductor device package 500 may have any number of electrical leads 518 having any suitable form without deviating from the scope of the present disclosure.

The power semiconductor device package 500 may further include a reinforcing structure 550. The reinforcing structure 550 may be similar to any of the reinforcing structures described herein, such as the reinforcing structure 150 (e.g., FIGS. 1-6C), the reinforcing structure 200 (e.g., FIGS. 7A-7D), the reinforcing structure 300 (FIGS. 8A-8D), the first reinforcing structure 400 and the second reinforcing structure 450 (FIG. 9), and/or the like. For instance, the reinforcing structure 550 may be spaced apart from the semiconductor die 104 on the submount 506. The reinforcing structure 550 may also be configured such that the structural robustness, rigidity, and/or the like, of the power semiconductor device package 500 is increased, thereby reducing an amount of warpage (and/or other thermomechanical-induced stressors) that would otherwise occur during and/or after the manufacturing, fabrication, packaging, and operation of the power semiconductor device package 500. That is, to counteract the bending force induced in the submount 506, the reinforcing structure 550 may have a different coefficient of thermal expansion (CTE) relative to the submount 206. In some examples, the reinforcing structure 550 may likewise have a different CTE relative to the encapsulating material that forms the housing 502. Additionally, the reinforcing structure 550 may also have a greater modulus of elasticity relative to the submount 506. For instance, in some examples, the reinforcing structure 550 may have a modulus of elasticity that is at least 1.5 times greater, such as at least 2 times greater, than a modulus of elasticity of the submount 206.

The reinforcing structure 550 may include the same and/or similar materials as that described above with reference to the reinforcing structures 150 (FIGS. 1-9). For instance, in some examples, the reinforcing structure 550 may include a metal and/or a metal alloy such as, by way of non-limiting example, aluminum (Al) and/or an aluminum-based alloy, a copper-zinc (CuZn) alloy, a nichrome alloy, an iron-chromium (FeCr) alloy, an iron-nickel (FeNi) alloy, a cobalt-chromium (CoCr) alloy, and/or the like. Additionally and/or alternatively, in some examples, the reinforcing structure 550 may include a non-metal material such as, by way of non-limiting example, a carbon fiber-based composite material, a ceramic-based material, and/or the like.

The reinforcing structure 550 may also be provided on the submount in any suitable manner, such as any manner similar to that of the reinforcing structure 150 (e.g., FIGS. 1-6C), the reinforcing structure 200 (e.g., FIGS. 7A-7D), the reinforcing structure 300 (FIGS. 8A-8D), the first reinforcing structure 400 and the second reinforcing structure 450 (FIG. 9), and/or the like. By way of non-limiting example, the reinforcing structure 550 may be brazed on the submount 506, laminated on the submount 506, plated on the submount 506, sintered on the submount 506, and/or the like. Those having ordinary skill in the art, using the disclosures provided herein, will understand that the reinforcing structure 550 may be provided on the submount 506 in any suitable manner without deviating from the scope of the present disclosure.

In some examples (e.g., FIGS. 10A-10C), the reinforcing structure 550 may be on a first side 508A of the submount 506, embedded in the first side 508A of the submount 506, and/or any suitable combination thereof. In such examples, the reinforcing structure 550 may have a greater CTE relative to the submount 506. The reinforcing structure 550 may further have a greater CTE relative to the encapsulating material that forms the housing 502.

Furthermore, the reinforcing structure 550 may have any suitable size, shape, configuration, arrangement, etc., without deviating from the scope of the present disclosure. For instance, as shown in FIGS. 10A-10C, the reinforcing structure 550 may be arranged outside of the die footprint 104′ on the first side 508A of the submount 506. In some examples (FIG. 10A), the reinforcing structure 550 may have a closed shape that extends around the semiconductor die 104 (e.g., outside of the die footprint 104′). More particularly, in some examples (FIG. 10A), the reinforcing structure 550 may have a rectangular shape. Additionally and/or alternatively, in some examples (FIGS. 10B-10C), the reinforcing structure 550 may have a non-rectangular shape. In some examples (FIG. 10A), the reinforcing structure 550 may extend to a periphery 534 of the first side 108A of the submount 506. In some examples, the reinforcing structure 200 may extend around a periphery 536 of die footprint 104′. It should be understood that the reinforcing structure 550 may have any suitable closed shape, such as any suitable rectangular and/or non-rectangular shape, without deviating from the scope of the present disclosure.

Additionally and/or alternatively, in some examples (FIGS. 10B-10C), the reinforcing structure 550 may have an open shape. More particularly, the reinforcing structure 550 may include a plurality of portions 552 that are different relative to one another. In some examples, the plurality of portions 552 may be a plurality of metal strips 554 in a similar manner as described herein. For instance, in some examples (FIG. 10B), the reinforcing structure 550 may have a first portion 552-1, a second portion 552-2, and a third portion 552-3. The second portion 552-2 and the third portion 552-3 of the reinforcing structure 550 may be parallel to one another and may be spaced apart from one another on opposing sides of the semiconductor die 104, while the first portion 552-1 may be perpendicular to, and may extend between, the second portion 552-2 and the third portion 552-3. In some examples (FIG. 10C), the reinforcing structure 550 may further include a fourth portion 552-4 and a fifth portion 552-5. The fourth portion 552-4 may be spaced apart from the fifth portion 552-5 on the first side 508A of the submount 506 and may be generally parallel to the first portion 552-1. Those having ordinary skill in the art, using the disclosures provided herein, will understand that the example reinforcing structure 550 may have any number of portions 552 without deviating from the scope of the present disclosure.

Additionally and/or alternatively, in some examples (FIGS. 11A-11C), the power semiconductor device package 500 may include a reinforcing structure 560 on a second side 508B of the submount 506. In some examples, the reinforcing structure 550 may be a first reinforcing structure 550, and the power semiconductor device package 500 may further include a second reinforcing structure, such as the reinforcing structure 560, on the second side 508B of the submount 506. In other examples, the power semiconductor device package 500 may only include only one reinforcing structure, such as the reinforcing structure 550 on the first side 508A of the submount 506 and/or the reinforcing structure 560 on the second side 508B of the submount 506.

More particularly, referring now to FIGS. 11A-11C, the power semiconductor device package 500 may include the reinforcing structure 560 on the second side 508B of the submount 506, embedded in the second side 508B of the submount 506, and/or any suitable combination thereof. In such examples, the reinforcing structure 560 may have a lower CTE relative to the submount 506. The reinforcing structure 560 may further have a lower CTE relative to the encapsulating material that forms the housing 502. The reinforcing structure 560 may further have a greater modulus of elasticity relative to the submount 506, such as a modulus of elasticity that is at least 1.5 times greater, such as at least 2 times greater, than a modulus of elasticity of the submount 506.

Furthermore, the reinforcing structure 560 may have any suitable size, shape, configuration, arrangement, etc., without deviating from the scope of the present disclosure. In some examples (FIG. 11A), the reinforcing structure 560 may have a closed, rectangular shape that is similar to that described above with reference to FIG. 10A. Additionally and/or alternatively, in some examples (FIGS. 11B-11C), the reinforcing structure 250 may have an open shape that is similar to that described above with reference to FIGS. 10B-10C.

FIGS. 10A-11C depict example reinforcing structures 550, 560 for purposes of illustration and discussion. Those of ordinary skill in the art, using the disclosures provided herein, will understand that different reinforcing structure configurations may be used without deviating from the scope of the present disclosure.

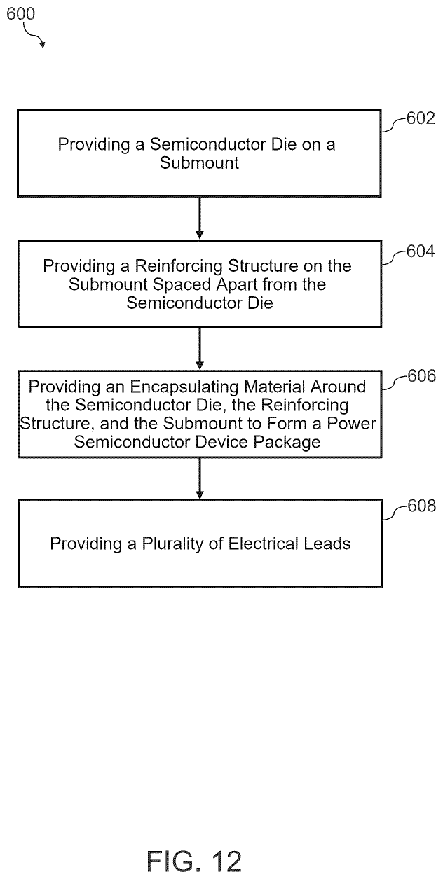

FIG. 12 depicts a flow chart diagram of an example method 600 according to example embodiments of the present disclosure. FIG. 12 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 602, the method 600 includes providing a semiconductor die on a submount. The submount may include a first side and a second side that is opposite the first side. The semiconductor die may include any suitable semiconductor device, such as, by way of non-limiting example, a metal-oxide-semiconductor field-effect transistor (MOSFET), a Schottky diode, and/or the like. In some examples, the semiconductor die may include a wide bandgap semiconductor material such as, by way of non-limiting example, silicon carbide (SiC), a Group III-nitride (e.g., gallium nitride (GaN)), and/or the like.

At 604, the method 600 includes providing a reinforcing structure on the submount spaced apart from the semiconductor die. The reinforcing structure may be provided on the semiconductor die in any suitable manner, such as brazing, laminating, plating, sintering, and/or the like. The reinforcing structure may include a different coefficient of thermal expansion (CTE) relative to the submount. The reinforcing structure may also include a greater modulus of elasticity relative to the submount. For instance, in some examples, the reinforcing structure may include a metal (e.g., aluminum (Al), etc.), a metal alloy (e.g., a copper-zinc (CuZn) alloy, a nichrome alloy, an iron-chromium (FeCr) alloy, an iron-nickel (FeNi) alloy, a cobalt-chromium (CoCr) alloy, etc.), a non-metal material (e.g., a carbon fiber-based composite material, a ceramic-based material, etc.), and/or the like.

In some examples, the method 600 may include providing the reinforcing structure on the first side of the submount. In such examples, the reinforcing structure may have a greater CTE relative to the submount. More particularly, in some examples, the method 600 may include providing the reinforcing structure on the first side of the submount such that the reinforcing structure extends around a periphery of a die footprint defined by the semiconductor die. Additionally and/or alternatively, in some examples, the method 600 may include providing the reinforcing structure outside of the die footprint on the first side of the submount. Additionally and/or alternatively, in some examples, the method 600 may include providing a plurality of metal strips outside of the die footprint on the first side of the submount.

In some examples, the method 600 may include providing the reinforcing structure on the second side of the submount. In such examples, the reinforcing structure may have a lower CTE relative to the submount. More particularly, in some examples, the method 600 may include providing the reinforcing structure on the submount such that the reinforcing structure extends around a periphery of the second side of the submount. Additionally and/or alternatively, in some examples, the method 600 may include providing a plurality of metal strips, such as an array of metal strips, on the second side of the submount.

In some examples, the method 600 may include embedding the reinforcing in the first side of the submount such that at least a portion of the reinforcing structure is co-planar with the first side of the submount and at least a second portion of the reinforcing structure is embedded within a thickness of the submount. Additionally and/or alternatively, in some examples, the method 600 may include embedding the reinforcing in the second side of the submount such that at least a portion of the reinforcing structure is co-planar with the second side of the submount and at least a second portion of the reinforcing structure is embedded within a thickness of the submount. In some examples, the reinforcing structure may include a first portion and a second portion that is different from the first portion. In such examples, the method 600 may include providing the reinforcing structure on the submount such that the first portion is embedded in the submount and the second portion is on the submount.

In some examples, the method 600 may include providing a first reinforcing structure on the first side of the submount and providing a second reinforcing structure on the second side of the submount. In such examples, the second reinforcing structure may be different from the first reinforcing structure. Furthermore, the first reinforcing structure may have a greater CTE relative to the submount, and the second reinforcing structure may have a lower CTE relative to the submount.

At 606, the method 600 includes providing an encapsulating material around the semiconductor die, the reinforcing structure, and the submount to form a power semiconductor device package. The encapsulating material may have a different CTE relative to the reinforcing structure (e.g., provided at 604). For instance, in some examples, the encapsulating material may be an epoxy mold compound (EMC), a ceramic-based encapsulating material, a silicon-based encapsulating material, a polymer-based encapsulating material, and/or the like.

At 608, the method 600 includes providing a plurality of electrical leads. As described herein, the encapsulating material (e.g., provided at 606) may form a housing for the power semiconductor device package. In such examples, the plurality of electrical leads (e.g., provided at 608) may extend from the housing.

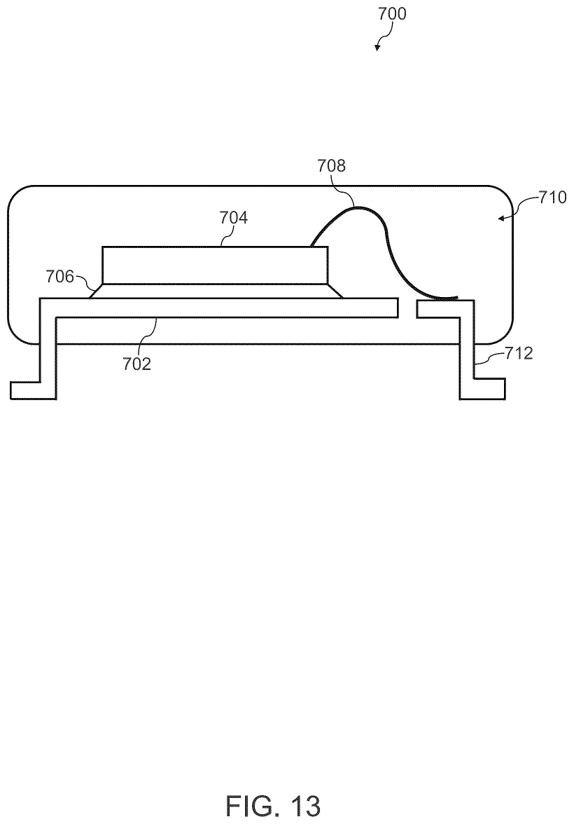

FIG. 13 depicts an example power semiconductor device package 700 of a power semiconductor device according to example embodiments of the present disclosure. The power semiconductor device package 700 may be, for instance, a discrete power semiconductor device package. FIG. 13 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 13 is intended to represent structures for identification and description and is not intended to represent the structures to physical scale.

As shown, the power semiconductor device package 100 may include a conductive submount 702 (e.g., a patterned conductive substrate, lead frame, clip structure or other power substrate) on which a semiconductor die 704 containing one or more power devices (e.g., transistors, diodes, etc.) is attached using a die-attach material 706. It should be understood that the semiconductor die 704 may correspond to any of the semiconductor die disclosed herein (e.g., semiconductor die 104, etc.) and may be fabricated using any of the methods disclosed herein. It should be further understood that the conductive submount 702 may correspond to any of the submounts disclosed herein (e.g., submount 106, submount 506, etc.) and may include any of the reinforcing structures disclosed herein (e.g., reinforcing structure 150, reinforcing structure 200, reinforcing structure 300, reinforcing structure 400 and/or reinforcing structure 450, reinforcing structure 550 and/or reinforcing structure 560, etc.).

The die-attach material 706 may provide a thermal, mechanical, and electrical connection between the semiconductor die 704 and the conductive submount 702. In some examples, the semiconductor die 704 may also be connected to the conductive submount 702 using wire bonds 708. An encapsulating material 710 (e.g., epoxy mold compound (EMC), ceramic-based encapsulating material, silicon-based encapsulating material, polymer-based encapsulating material, etc.) may fill the space around the semiconductor die 704 and the submount 702, thereby forming a housing. The power semiconductor device package 700 may further include one or more connection structures, such as electrical leads 712, that extend outward from the housing (e.g., outward from the encapsulating material 710).

The power semiconductor device package 1100 may include one or more metallization structures, such as any of the metallization structures disclosed herein. More particularly, the semiconductor die 704 may include one or more metallization structures, such as bonding pads. The bonding pads may be coupled to the one or more electrical leads 712 using the wire bonds 708. The wire bonds 708 may be aluminum and/or copper. The wire bonds 708 may have a thickness of about 15 mil to about 20 mil (e.g., about 381 μm to about 508 μm). As noted above, the bonding pads may have a thickness, for instance, of about 4 μm or less. A backside metallization layer on the semiconductor die 704 may be coupled to the submount 702 (e.g., lead frame) using, for instance, the die-attach material 706. The encapsulating material 710 may encapsulate the semiconductor die 704, including its metallization structures, wire bonds 708, submount 702, and other portions of the power semiconductor device package 700. In some examples, the encapsulating material 710 may directly contact the metallization structures (e.g., bonding pads, backside metallization layer, etc.) of the power semiconductor device package 700.

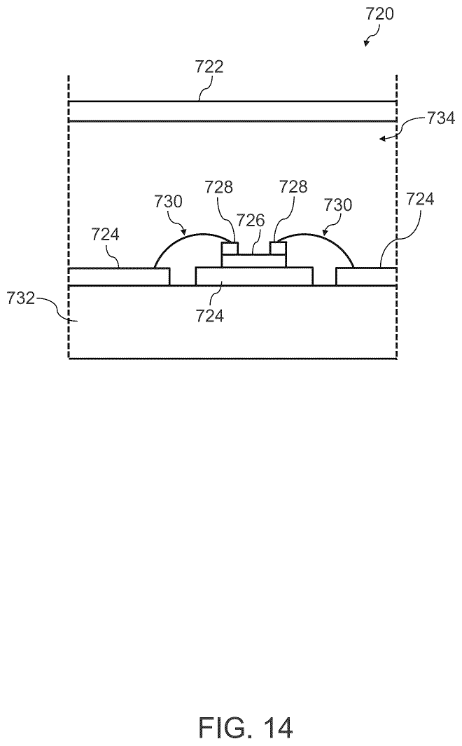

FIG. 14 depicts a cross-sectional view of an example power semiconductor device package of a semiconductor device 720 according to example embodiments of the present disclosure. The semiconductor device 720 of FIG. 14 is a portion of a power module. FIG. 14 is intended to represent structures for identification and description and is not intended to represent the structures to physical scale. The semiconductor device 720 may include a housing 722. The semiconductor device 720 may include a conductive submount 724 (e.g., a patterned conductive submount) on which a semiconductor die 726 is mounted (e.g., using a die-attach material). It should be understood that the semiconductor die 726 may correspond to any of the semiconductor die disclosed herein (e.g., semiconductor die 104, etc.) and may be fabricated using any of the methods disclosed herein. For instance, the semiconductor die 726 may be mounted on submount 724 using a die-attach material that includes a sintered material, such as sintered silver and/or sintered copper. The submount 724 may be similar to any of the submounts described herein (e.g., submount 106, submount 506, etc.). Furthermore, the submount 724 may include any of the reinforcing structures described herein (e.g., reinforcing structure 150, reinforcing structure 200, reinforcing structure 300, reinforcing structure 400 and/or reinforcing structure 450, reinforcing structure 550 and/or reinforcing structure 560, etc.). The semiconductor die 726 may include one or more metallization structures, such as bonding pads 728. In some examples, the semiconductor die 726 may be connected to the conductive submount 724 using wire bonds 730. The conductive submount 724 may be mounted on a base layer 732 (e.g., an insulating layer). An inert gel 734 may fill the space between the semiconductor die 726 and the housing 722.

FIGS. 13-14 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a power semiconductor device package. The power semiconductor device package includes a submount comprising a first side and a second side opposite the first side. The power semiconductor device package further includes a semiconductor die on the first side of the submount. The power semiconductor device package further includes a reinforcing structure on the submount, the reinforcing structure spaced apart from the semiconductor die, the reinforcing structure comprising a different coefficient of thermal expansion (CTE) relative to the submount. The power semiconductor device package further includes a housing comprising an encapsulating material formed around at least a portion of the submount.

In some examples, the reinforcing structure includes a first portion and a second portion that is different from the first portion. In some examples, the first portion of the reinforcing structure is embedded in the submount. In some examples, the second portion of the reinforcing structure is on the submount.

In some examples, the reinforcing structure includes a greater modulus of elasticity relative to the submount.

In some examples, the reinforcing structure includes a first modulus of elasticity. In some examples, the submount includes a second modulus of elasticity. In some examples, the first modulus of elasticity is at least 1.5 times greater than the second modulus of elasticity.

In some examples, the first modulus of elasticity is at least 2 times greater than the second modulus of elasticity.

In some examples, the reinforcing structure is on the first side of the submount.

In some examples, a surface of the semiconductor die defines a die footprint, and the reinforcing structure extends around a periphery of the die footprint.

In some examples, a surface of the semiconductor die defines a die footprint, and the reinforcing structure is outside of the die footprint on the first side of the submount.

In some examples, the reinforcing structure includes a greater CTE relative to the submount.

In some examples, the reinforcing structure includes a closed shape, the closed shape extending around the semiconductor die.

In some examples, the reinforcing structure includes an open shape, the open shape including a first portion spaced apart from an opposing second portion.

In some examples, the reinforcing structure includes a plurality of metal strips on the first side of the submount.

In some examples, the plurality of metal strips includes at least a first metal strip and a second metal strip that is different from the first metal strip, the first metal strip being generally parallel to the second metal strip In some examples, a surface of the semiconductor die defines a die footprint, and the first metal strip and the second metal strip are outside of the die footprint on opposite sides of the semiconductor die relative to one another.

In some examples, the reinforcing structure is on the second side of the submount.

In some examples, the reinforcing structure includes a lower CTE relative to the submount.

In some examples, the reinforcing structure extends around a periphery of the second side of the submount.

In some examples, the reinforcing structure includes a plurality of metal strips on the second side of the submount.

In some examples, at least two of the plurality of metal strips are generally perpendicular relative to one another.

In some examples, at least two of the plurality of metal strips intersect with one another.

In some examples, the plurality of metal strips includes an array of metal strips, each of the array of metal strips being spaced apart on the second side of the submount.

In some examples, the reinforcing structure is embedded in the submount.

In some examples, the reinforcing structure is embedded in the first side of the submount. In some examples, at least a first portion of the reinforcing structure is co-planar with the first side of the submount, and at least a second portion of the reinforcing structure is embedded within a thickness of the submount.

In some examples, the reinforcing structure is embedded in the second side of the submount. In some examples, at least a first portion of the reinforcing structure is co-planar with the second side of the submount, and at least a second portion of the reinforcing structure is embedded within a thickness of the submount.

In some examples, a thickness of the reinforcing structure is in a range of about 0.05 millimeters to about 2 millimeters.

In some examples, the thickness of the reinforcing structure is in a range of about 0.1 millimeters to about 1 millimeter.

In some examples, the reinforcing structure is one of brazed on the submount, laminated on the submount, plated on the submount, or sintered on the submount.

In some examples, the reinforcing structure includes a metal.

In some examples, the reinforcing structure includes aluminum (Al).

In some examples, the reinforcing structure includes a metal alloy. In some examples, the metal alloy is one of a copper-zinc (CuZn) alloy, a nichrome alloy, an iron-chromium (FeCr) alloy, an iron-nickel (FeNi) alloy, or a cobalt-chromium (CoCr) alloy.

In some examples, the reinforcing structure includes a non-metal material, the non-metal material being one of a carbon fiber-based composite material or a ceramic-based material.

In some examples, the submount includes copper (Cu).

In some examples, the submount is a lead frame.

In some examples, the submount is a power substrate, the power substrate including a plurality of metal layers and an insulating layer between the metal layers.

In some examples, the power substrate is one of a direct bonded copper (DBC) substrate or an active metal brazed (AMB) substrate.

In some examples, the reinforcing structure includes a different CTE relative to the encapsulating material.

In some examples, the encapsulating material directly contacts at least a portion of the submount.

In some examples, the encapsulating material includes an epoxy mold compound (EMC).

In some examples, the encapsulating material includes one of a ceramic-based encapsulating material, a silicon-based encapsulating material, or a polymer-based encapsulating material.

In some examples, the power semiconductor device package further includes a plurality of electrical leads extending from the housing.

In some examples, the semiconductor die includes one of a metal-oxide-semiconductor field-effect transistor (MOSFET) or a Schottky diode.

In some examples, the semiconductor die includes a wide bandgap semiconductor material. In some examples, the wide bandgap semiconductor material is one of silicon carbide (SiC) or a Group III-nitride.

In some examples, the power semiconductor device package is one of a discrete power semiconductor device package or a power module.

Another example aspect of the present disclosure is directed to a power semiconductor device package. The power semiconductor device package includes a submount comprising a first side and a second side opposite the first side. The power semiconductor device package further includes a semiconductor die on the first side of the submount. The power semiconductor device package further includes a first reinforcing structure on the first side of the submount. The power semiconductor device package further includes a second reinforcing structure on the second side of the submount, the second reinforcing structure being different from the first reinforcing structure. The power semiconductor device package further includes a housing comprising an encapsulating material formed around at least a portion of the submount.

In some examples, each of the first reinforcing structure and the second reinforcing structure includes a different coefficient of thermal expansion (CTE) relative to the submount.

In some examples, the first reinforcing structure includes a greater CTE relative to the submount.

In some examples, the second reinforcing structure includes a lower CTE relative to the submount.

In some examples, each of the first reinforcing structure and the second reinforcing structure includes a greater modulus of elasticity relative to the submount.

In some examples, a surface of the semiconductor die defines a die footprint, and the first reinforcing structure extends around a periphery of the die footprint.

In some examples, a surface of the semiconductor die defines a die footprint, and the first reinforcing structure is outside of the die footprint on the first side of the submount.

In some examples, the first reinforcing structure includes a closed shape, the closed shape extending around the semiconductor die.

In some examples, the first reinforcing structure includes an open shape, the open shape including a first portion spaced apart from an opposing second portion.

In some examples, the first reinforcing structure includes a plurality of metal strips, the plurality of metal strips including at least a first metal strip and a second metal strip that is different from the first metal strip, the first metal strip being generally parallel to the second metal strip. In some examples, a surface of the semiconductor die defines a die footprint, and the first metal strip and the second metal strip are outside of the die footprint on opposite sides of the semiconductor die relative to one another.

In some examples, the second reinforcing structure extends around a periphery of the second side of the submount.

In some examples, the second reinforcing structure includes a plurality of metal strips on the second side of the submount.

In some examples, at least two of the plurality of metal strips one of are generally perpendicular relative to one another or intersect with one another.

In some examples, the plurality of metal strips includes an array of metal strips, each of the array of metal strips being spaced apart on the second side of the submount.

In some examples, at least one of the first reinforcing structure and the second reinforcing structure is embedded in the submount.

In some examples, the first reinforcing structure is embedded in the first side of the submount. In some examples, at least a first portion of the first reinforcing structure is co-planar with the first side of the submount, and at least a second portion of the first reinforcing structure is embedded within a thickness of the submount.

In some examples, the second reinforcing structure is embedded in the second side of the submount. In some examples, at least a first portion of the second reinforcing structure is co-planar with the second side of the submount, and at least a second portion of the second reinforcing structure is embedded within a thickness of the submount.

In some examples, each of the first reinforcing structure and the second reinforcing structure are one of brazed on the submount, laminated on the submount, plated on the submount, or sintered on the submount.

In some examples, at least one of the first reinforcing structure and the second reinforcing structure includes a metal.

In some examples, at least one of the first reinforcing structure and the second reinforcing structure includes a metal alloy. In some examples, the metal alloy is one of a copper-zinc (CuZn) alloy, a nichrome alloy, an iron-chromium (FeCr) alloy, an iron-nickel (FeNi) alloy, or a cobalt-chromium (CoCr) alloy.

In some examples, at least one of the first reinforcing structure and the second reinforcing structure includes a non-metal material, the non-metal material being one of a carbon fiber-based composite material or a ceramic-based material.

In some examples, the submount is one of a lead frame or a power substrate. In some examples, the power substrate includes a plurality of metal layers and an insulating layer between the metal layers.

In some examples, the encapsulating material directly contacts at least a portion of the submount.

In some examples, the encapsulating material includes one of an epoxy mold compound (EMC), a ceramic-based encapsulating material, a silicon-based encapsulating material, or a polymer-based encapsulating material.

In some examples, the power semiconductor device package further includes a plurality of electrical leads extending from the housing.

In some examples, the semiconductor die is one of a metal-oxide-semiconductor field-effect transistor (MOSFET) or a Schottky diode.

In some examples, the semiconductor die includes a wide bandgap semiconductor material, the wide bandgap semiconductor material being one of silicon carbide (SiC) or a Group III-nitride.

In some examples, the power semiconductor device package is one of a discrete power semiconductor device package or a power module.

Another example aspect of the present disclosure is directed to a method. The method includes providing a semiconductor die on a submount. The method further includes providing a reinforcing structure on the submount spaced apart from the semiconductor die, the reinforcing structure comprising a different coefficient of thermal expansion (CTE) relative to the submount. The method further includes providing an encapsulating material around the semiconductor die, the reinforcing structure, and the submount to form a power semiconductor device package.

In some examples, the reinforcing structure includes a first portion and a second portion that is different from the first portion. In some examples, providing the reinforcing structure on the submount spaced apart from the semiconductor die includes providing the reinforcing structure on the submount such that the first portion is embedded in the submount and the second portion is on the submount.

In some examples, the submount includes a first side and a second side that is opposite the first side. In some examples, providing the reinforcing structure on the submount spaced apart from the semiconductor die includes providing the reinforcing structure on the first side of the submount, the reinforcing structure including a greater CTE relative to the submount.

In some examples, a surface of the semiconductor die defines a die footprint. In some examples, providing the reinforcing structure on the first side of the submount includes providing the reinforcing structure on the first side of the submount such that the reinforcing structure extends around a periphery of the die footprint.

In some examples, a surface of the semiconductor die defines a die footprint. In some examples, providing the reinforcing structure on the first side of the submount includes providing the reinforcing structure outside of the die footprint on the first side of the submount.

In some examples, the reinforcing structure includes one of a closed shape extending around the semiconductor die or an open shape including a first portion spaced apart from an opposing second portion.

In some examples, a surface of the semiconductor die defines a die footprint. In some examples, providing the reinforcing structure on the first side of the submount includes providing a plurality of metal strips outside of the die footprint on the first side of the submount.

In some examples, providing the plurality of metal strips outside of the die footprint on the first side of the submount includes providing a first metal strip of the plurality of metal strips outside of the die footprint on the first side of the submount and providing a second metal strip of the plurality of metal strips outside of the die footprint on the first side of the submount on an opposite side of the semiconductor die relative to the first metal strip, the first metal strip being generally parallel to the second metal strip.

In some examples, the submount includes a first side and a second side that is opposite the first side. In some examples, providing the reinforcing structure on the submount spaced apart from the semiconductor die includes providing the reinforcing structure on the second side of the submount, the reinforcing structure including a lower CTE relative to the submount.

In some examples, providing the reinforcing structure on the second side of the submount includes providing the reinforcing structure on the second side of the submount such that the reinforcing structure extends around a periphery of the second side of the submount.

In some examples, providing the reinforcing structure on the second side of the submount includes providing a plurality of metal strips on the second side of the submount.

In some examples, providing the plurality of metal strips on the second side of the submount includes one of providing an array of metal strips on the second side of the submount, each of the array of metal strips being spaced apart on the second side of the submount, providing the plurality of metal strips on the second side of the submount such that at least two of the plurality of metal strips are generally perpendicular relative to one another, or providing the plurality of metal strips on the second side of the submount such that at least two of the plurality of metal strips intersect with one another.

In some examples, the submount includes a first side and a second side that is opposite the first side. In some examples, providing the reinforcing structure on the submount spaced apart from the semiconductor die includes embedding the reinforcing structure in the first side of the submount, at least a first portion of the reinforcing structure being co-planar with the first side of the submount, at least a second portion of the reinforcing structure being embedded within a thickness of the submount.

In some examples, the submount includes a first side and a second side that is opposite the first side. In some examples, providing the reinforcing structure on the submount spaced apart from the semiconductor die includes embedding the reinforcing structure in the second side of the submount, at least a first portion of the reinforcing structure being co-planar with the second side of the submount, at least a second portion of the reinforcing structure being embedded within a thickness of the submount.

In some examples, the submount includes a first side and a second side that is opposite the first side. In some examples, providing the reinforcing structure on the submount spaced apart from the semiconductor die includes providing a first reinforcing structure on the first side of the submount, the first reinforcing structure including a greater CTE relative to the submount and providing a second reinforcing structure on the second side of the submount, the second reinforcing structure including a lower CTE relative to the submount, the second reinforcing structure being different from the first reinforcing structure.

In some examples, providing the reinforcing structure on the submount spaced apart from the semiconductor die includes one of brazing the reinforcing structure on the submount, laminating the reinforcing structure on the submount, plating the reinforcing structure on the submount, or sintering the reinforcing structure on the submount.

In some examples, the reinforcing structure includes one of a metal or a metal alloy. In some examples, the metal alloy is one of a copper-zinc (CuZn) alloy, a nichrome alloy, an iron-chromium (FeCr) alloy, an iron-nickel (FeNi) alloy, or a cobalt-chromium (CoCr) alloy.

In some examples, the reinforcing structure includes a non-metal material, the non-metal material being one of a carbon fiber-based composite material or a ceramic-based material.

In some examples, the reinforcing structure includes a greater modulus of elasticity relative to the submount.

In some examples, providing the encapsulating material includes providing the encapsulating material directly on at least a portion of the submount.

In some examples, the reinforcing structure includes a different CTE relative to the encapsulating material.

In some examples, the encapsulating material includes one of an epoxy mold compound (EMC), a ceramic-based encapsulating material, a silicon-based encapsulating material, or a polymer-based encapsulating material.

In some examples, the encapsulating material forms a housing for the power semiconductor device package. In some examples, the method further includes providing a plurality of electrical leads, the plurality of electrical leads extending from the housing.

In some examples, the semiconductor die includes one of a metal-oxide-semiconductor field-effect transistor (MOSFET) or a Schottky diode.

In some examples, the semiconductor die includes a wide bandgap semiconductor material, the wide bandgap semiconductor material being one of silicon carbide (SiC) or a Group III-nitride.

Another example aspect of the present disclosure is directed to a power semiconductor device package. The power semiconductor device package includes a submount comprising a first side and a second side opposite the first side. The power semiconductor device package includes a semiconductor die on the first side of the submount. The power semiconductor device package further includes a reinforcing structure on the submount, the reinforcing structure spaced apart from the semiconductor die, the reinforcing structure comprising a greater modulus of elasticity relative to the submount. The power semiconductor device package further includes a housing comprising an encapsulating material formed around at least a portion of the submount.

Another example aspect of the present disclosure is directed to a power semiconductor device package. The power semiconductor device package includes a submount comprising a first side and a second side that is opposite the first side. The power semiconductor device package further includes a semiconductor die on the first side of the submount. The power semiconductor device package further includes a reinforcing structure on the first side of the submount, the reinforcing structure spaced apart from the semiconductor die, the reinforcing structure comprising a greater coefficient of thermal expansion (CTE) relative to the submount. The power semiconductor device package further includes a housing comprising an encapsulating material formed around at least a portion of the submount.

Another example aspect of the present disclosure is directed to a power semiconductor device package. The power semiconductor device package includes a submount comprising a first side and a second side that is opposite the first side. The power semiconductor device package further includes a semiconductor die on the first side of the submount. The power semiconductor device package further includes a reinforcing structure on the second side of the submount, the reinforcing structure comprising a lower coefficient of thermal expansion (CTE) relative to the submount. The power semiconductor device package further includes a housing comprising an encapsulating material formed around at least a portion of the submount.

In some examples, the reinforcing structure is embedded in the second side of the submount.

In some examples, at least a first portion of the reinforcing structure is co-planar with the second side of the submount, and at least a second portion of the reinforcing structure is embedded within a thickness of the submount.

Another example aspect of the present disclosure is directed to a power semiconductor device package. The power semiconductor device package includes a submount comprising a first side and a second side opposite the first side. The power semiconductor device package further includes a semiconductor die on the first side of the submount. The power semiconductor device package further includes a reinforcing structure embedded in the submount, the reinforcing structure comprising a different coefficient of thermal expansion (CTE) relative to the submount. The power semiconductor device package further includes a housing comprising an encapsulating material formed around at least a portion of the submount.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device package, comprising:
a submount comprising a first side and a second side opposite the first side;
a semiconductor die on the first side of the submount;
a reinforcing structure on the submount, the reinforcing structure spaced apart from the semiconductor die, the reinforcing structure comprising a different coefficient of thermal expansion (CTE) relative to the submount; and
a housing comprising an encapsulating material formed around at least a portion of the submount.

2. The power semiconductor device package of claim 1, wherein the reinforcing structure comprises a first portion and a second portion that is different from the first portion, and wherein:
the first portion of the reinforcing structure is embedded in the submount; and
the second portion of the reinforcing structure is on the submount.

3. The power semiconductor device package of claim 1, wherein the reinforcing structure comprises a greater modulus of elasticity relative to the submount.

4. The power semiconductor device package of claim 1, wherein the reinforcing structure is on the first side of the submount.

5. The power semiconductor device package of claim 4, wherein:
a surface of the semiconductor die defines a die footprint; and
the reinforcing structure extends around a periphery of the die footprint.

6. The power semiconductor device package of claim 4, wherein:
a surface of the semiconductor die defines a die footprint; and
the reinforcing structure is outside of the die footprint on the first side of the submount.

7. The power semiconductor device package of claim 4, wherein the reinforcing structure comprises a greater CTE relative to the submount.

8. The power semiconductor device package of claim 4, wherein the reinforcing structure comprises a closed shape, the closed shape extending around the semiconductor die.

9. The power semiconductor device package of claim 4, wherein the reinforcing structure comprises an open shape, the open shape comprising a first portion spaced apart from an opposing second portion.

10. The power semiconductor device package of claim 1, wherein the reinforcing structure is on the second side of the submount.

11. The power semiconductor device package of claim 10, wherein the reinforcing structure comprises a lower CTE relative to the submount.

12. The power semiconductor device package of claim 10, wherein the reinforcing structure extends around a periphery of the second side of the submount.

13. The power semiconductor device package of claim 1, wherein the reinforcing structure is embedded in the submount.

14. The power semiconductor device package of claim 13, wherein the reinforcing structure is embedded in the first side of the submount, and wherein:
at least a first portion of the reinforcing structure is co-planar with the first side of the submount; and
at least a second portion of the reinforcing structure is embedded within a thickness of the submount.

15. The power semiconductor device package of claim 13, wherein the reinforcing structure is embedded in the second side of the submount, and wherein:
at least a first portion of the reinforcing structure is co-planar with the second side of the submount; and
at least a second portion of the reinforcing structure is embedded within a thickness of the submount.

16. The power semiconductor device package of claim 1, wherein the reinforcing structure comprises a metal.

17. The power semiconductor device package of claim 1, wherein the reinforcing structure comprises a non-metal material, the non-metal material being one of:
a carbon fiber-based composite material; or
a ceramic-based material.

18. The power semiconductor device package of claim 1, wherein the reinforcing structure comprises a different CTE relative to the encapsulating material.

19. A power semiconductor device package, comprising:
a submount comprising a first side and a second side opposite the first side;
a semiconductor die on the first side of the submount;
a first reinforcing structure on the first side of the submount;
a second reinforcing structure on the second side of the submount, the second reinforcing structure being different from the first reinforcing structure; and
a housing comprising an encapsulating material formed around at least a portion of the submount.

20. A power semiconductor device package, comprising:
a submount comprising a first side and a second side opposite the first side;
a semiconductor die on the first side of the submount;
a reinforcing structure embedded in the submount, the reinforcing structure comprising a different coefficient of thermal expansion (CTE) relative to the submount; and
a housing comprising an encapsulating material formed around at least a portion of the submount.
